(19) United States
(12) Patent Application Publication
(10) Pub. No.: US 2026/0206311 A1
(43) Pub. Date: Jul. 16, 2026

(54) INTEGRATED CIRCUIT DEVICE

(71) Applicant: SAMSUNG ELECTRONICS CO., LTD., Suwon-si (KR)

(72) Inventors: Sangwoo HAN, Suwon-si (KR); Kyuman HWANG, Suwon-si (KR); Jae Hyun PARK, Suwon-si (KR); Juhun PARK, Suwon-si (KR)

(73) Assignee: SAMSUNG ELECTRONICS CO., LTD., Suwon-si (KR)

(21) Appl. No.: 19/276,429

(22) Filed: Jul. 22, 2025

(30) Foreign Application Priority Data
Jan. 14, 2025 (KR) 10-2025-0005688

(51) Int. Cl. H10D 84/85; H10D 84/01

(52) U.S. Cl. CPC H10D 84/856; H10D 84/0167; H10D 84/017; H10D 84/0186; H10D 84/851

(57) ABSTRACT

An integrated circuit device includes a plurality of first source/drain areas, a plurality of second source/drain areas spaced apart from the plurality of first source/drain areas in a first direction and stacked above the plurality of first source/drain areas in the first direction, a first contact disposed on a lower surface of each of the plurality of first source/drain areas in the first direction, a second contact disposed on an upper surface of each of the plurality of second source/drain areas in the first direction, a conductive rail electrically connected to the first contact or the second contact and extending in the first direction, a first diffusion breaker disposed beside the conductive rail in a second direction intersecting the first direction, and a second diffusion breaker spaced apart from the first diffusion breaker in the second direction with the conductive rail in between.

### CROSS-REFERENCE TO RELATED APPLICATIONS

This application claims the benefit of Korean Patent Application No. 10-2025-0005688, filed on Jan. 14, 2025, in the Korean Intellectual Property Office, the disclosure of which is incorporated herein by reference in its entirety.

### BACKGROUND

### 1. Field of the Invention

The present disclosure relates to an integrated circuit device. Specifically, the present disclosure relates to an integrated circuit device including a field-effect transistor.

### 2. Description of the Related Art

As miniaturization, multi-functionalization, and high-performance of an electronic product are required, a high-capacity integrated circuit device is required. In order to provide the high-capacity integrated circuit device, increased integration density is required. For example, small-sized field-effect transistors may decrease an area of an integrated circuit. However, an operation speed may be decreased due to complexity of a wiring structure for small-sized devices. Thus, designing an integrated circuit device in consideration of integration density and performance may be important for achieving functions and an operation speed required for the integrated circuit device.

### SUMMARY

An aspect provides an integrated circuit including a field-effect transistor with improved integration density and electrical performance.

However, the goals to be achieved by example embodiments of the present disclosure are not limited to the objectives described above and other objects may be clearly understood from the following example embodiments by those skilled in the art.

According to an aspect, there is provided an integrated circuit device including a plurality of first source/drain areas, a plurality of second source/drain areas spaced apart from the plurality of first source/drain areas in a first direction and stacked above the plurality of first source/drain areas in the first direction, a first contact disposed on a lower surface of each of the plurality of first source/drain areas in the first direction, a second contact disposed on an upper surface of each of the plurality of second source/drain areas in the first direction, a conductive rail electrically connected to the first contact or the second contact and extending in the first direction, a first diffusion breaker disposed beside the conductive rail in a second direction intersecting the first direction, and a second diffusion breaker spaced apart from the first diffusion breaker in the second direction with the conductive rail in between, and the conductive rail overlaps the first diffusion breaker and the second diffusion breaker in the second direction.

According to another aspect, there is also provided an integrated circuit device including a plurality of first transistors including a plurality of first source/drain areas, a plurality of lower nanosheets connected to the plurality of first source/drain areas and spaced apart from each other in a first direction, a first gate line surrounding the plurality of lower nanosheets, and a first contact disposed on a lower surface of each of the plurality of first source/drain areas in the first direction, a plurality of second transistors including a plurality of second source/drain areas, a plurality of upper nanosheets connected to the plurality of second source/drain areas and spaced apart from each other in the first direction, a second gate line surrounding the plurality of upper nanosheets, and a second contact disposed on an upper surface of each of the plurality of second source/drain areas in the first direction, a plurality of conductive rails each extending in the first direction to connect one of the plurality of first transistors and one of the plurality of second transistors, a first diffusion breaker disposed beside one of the plurality of conductive rails in a second direction intersecting the first direction, a second diffusion breaker spaced apart from the first diffusion breaker in the second direction with the one of the plurality of conductive rails in between, and a gate separation structure positioned between a pair of second transistors adjacent in a third direction intersecting the first direction and the second direction among the plurality of second transistors, and the conductive rails overlap the first diffusion breaker and the second diffusion breaker in the second direction.

According to still another aspect, there is provided an integrated circuit device including a plurality of first source/drain areas, a first contact disposed on a lower surface of each of the plurality of first source/drain areas in a first direction, a plurality of lower nanosheets connected to the plurality of first source/drain areas and spaced apart from each other in the first direction, a first gate line surrounding the plurality of lower nanosheets and extending in a second direction intersecting the first direction, a plurality of second source/drain areas spaced apart from the plurality of first source/drain areas in the first direction and stacked above the plurality of first source/drain areas in the first direction, a second contact disposed on a lower surface of each of the plurality of second source/drain areas in the first direction, a plurality of upper nanosheets connected to the plurality of second source/drain areas and spaced apart from each other in the first direction, a second gate line surrounding the plurality of upper nanosheets and extending in the second direction, a conductive rail electrically connected to the first contact and the second contact and extending in the first direction, a first diffusion breaker that is disposed beside the conductive rail in a third direction intersecting the first direction and the second direction and is in contact with a side surface of the first gate line and a side surface of the second gate line in the second direction; and a second diffusion breaker spaced apart from the first diffusion breaker in the third direction with the conductive rail in between, and the conductive rail completely overlaps the first diffusion breaker and the second diffusion breaker in the third direction.

According to still another aspect, there is also provided a method of manufacturing an integrated circuit, the method including forming, above a substrate, a plurality of lower nanosheets and a plurality of second upper nanosheets spaced apart from the plurality of lower nanosheets in a first direction, forming a plurality of first source/drain areas positioned in a second direction intersecting the first direction from the plurality of lower nanosheets and a plurality of second source/drain areas positioned in the second direction from the plurality of upper nanosheets, forming a first gate electrode surrounding the plurality of lower nanosheets and extending in a third direction intersecting the first direction and the second direction and a second gate electrode surrounding the plurality of upper nanosheets and intersecting in the third direction, forming a gate separation structure intersecting the first gate electrode and the second gate electrode in the second direction, forming a first diffusion breaker and a second diffusion breaker overlapping the gate separation structure in the first direction and spaced apart from each other in the second direction, forming an opening portion by etching a portion of the gate separation structure by using an etch selectivity between the gate separation structure, the first diffusion breaker, and the second diffusion breaker, and forming a conductive rail by filling the opening portion with a conductive material.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a schematic layout diagram illustrating an integrated circuit device according to an example embodiment of the present disclosure;

FIG. 2 is an example diagram illustrating a cross section taken along line A1-A1′ of FIG. 1;

FIG. 3 is an example diagram illustrating a cross section taken along line A2-A2′ of FIG. 1;

FIG. 4 is an example diagram illustrating a cross section taken along line B1-B1′ of FIG. 1;

FIG. 5 is an example diagram illustrating a cross section taken along line B2-B2′ of FIG. 1;

FIG. 6 is an example diagram illustrating a cross section taken along line B3-B3′ of FIG. 1;

FIG. 7 is another example diagram illustrating a cross section taken along line A2-A2′ of FIG. 1;

FIG. 8 is still another example diagram illustrating a cross section taken along line A2-A2′ of FIG. 1;

FIG. 9 is a schematic layout diagram illustrating an integrated circuit device according to another example embodiment of the present disclosure;

FIG. 10 is a schematic layout diagram illustrating an integrated circuit device according to another example embodiment of the present disclosure;

FIGS. 11, 12, 13A, 13B, 14A, 14B, 15A, 15B, 15C, 16A, 16B, 16C, 17A, 17B, 17C, 17D, 17E, 18A, 18B, 18C, 18D, 18E, 19A, 19B, 19C, 20A, 20B, 21A, 21B, 21C, 22A, 22B, 23, 24A, 24B, 25A, and 25B are cross-sectional diagrams illustrating, in process order, a method of manufacturing an integrated circuit device according to an example embodiment of the present disclosure;

FIGS, 15A, 16A, 18A, 20A, and 21A are layout diagrams;

FIGS. 11, 12, 13A, 14A, 15B, 17B, 18B, 22A, 23, 24A, and 25A are diagrams corresponding to a cross section taken along line A1-A1′ of FIG. 1;

FIGS. 16B, 17C, 18C, 19B, 20B, and 21B are diagrams corresponding to a cross section taken along line A2-A2′ of FIG. 1;

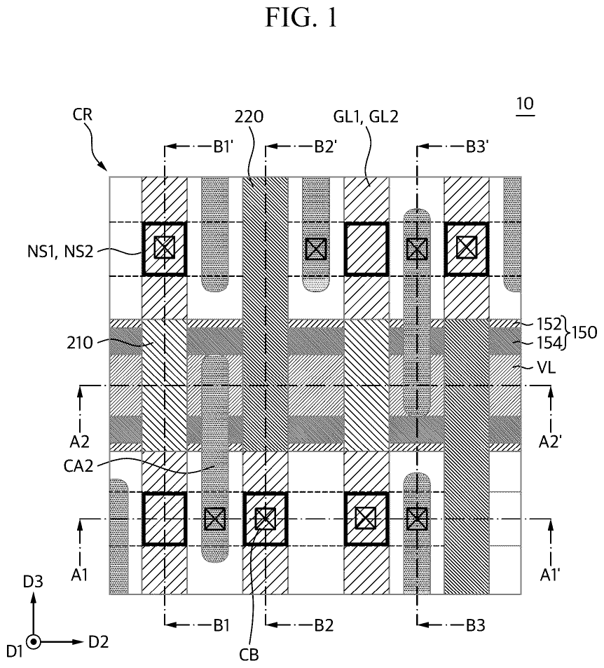

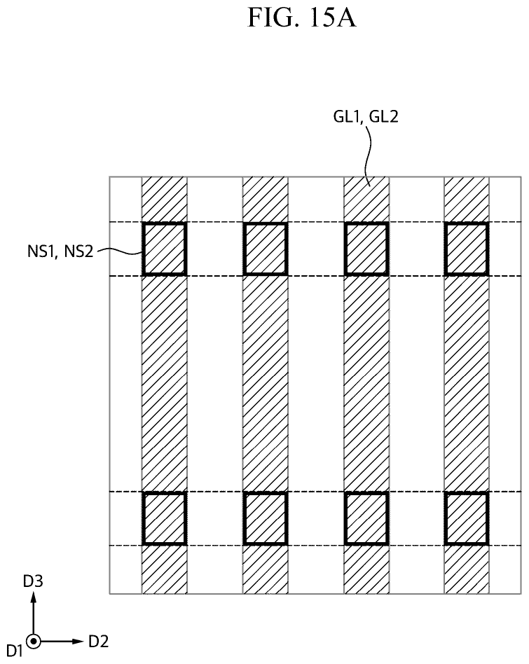

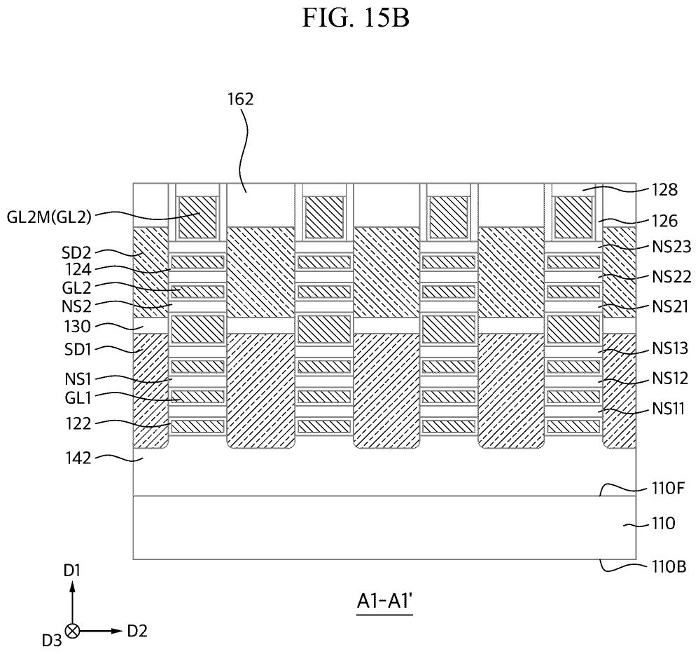

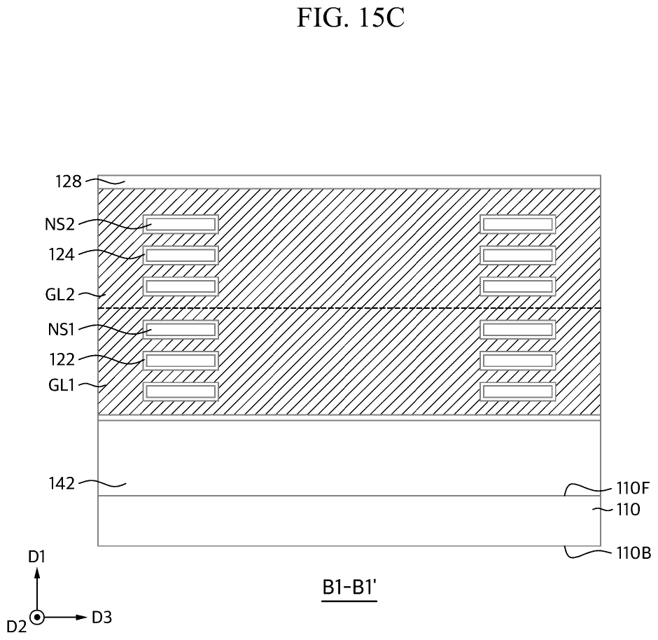

FIGS. 15C, 17D, and 18D are diagrams corresponding to a cross section taken along line B1-B1′ of FIG. 1; and

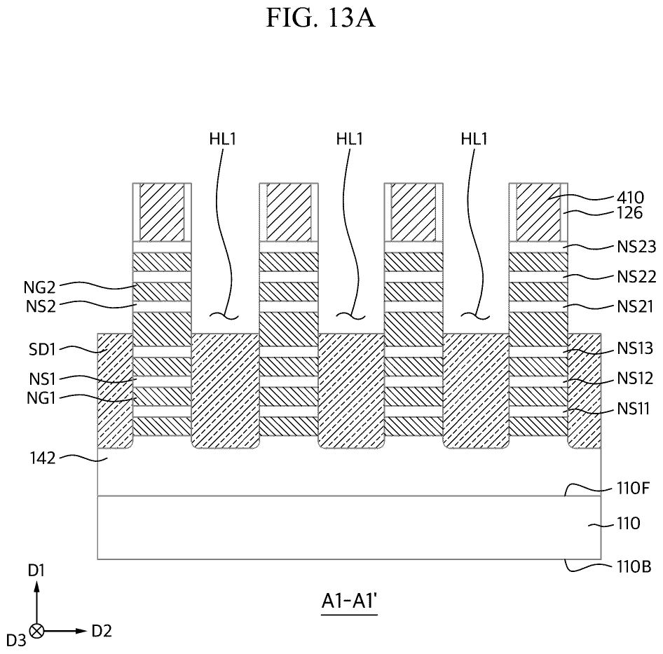

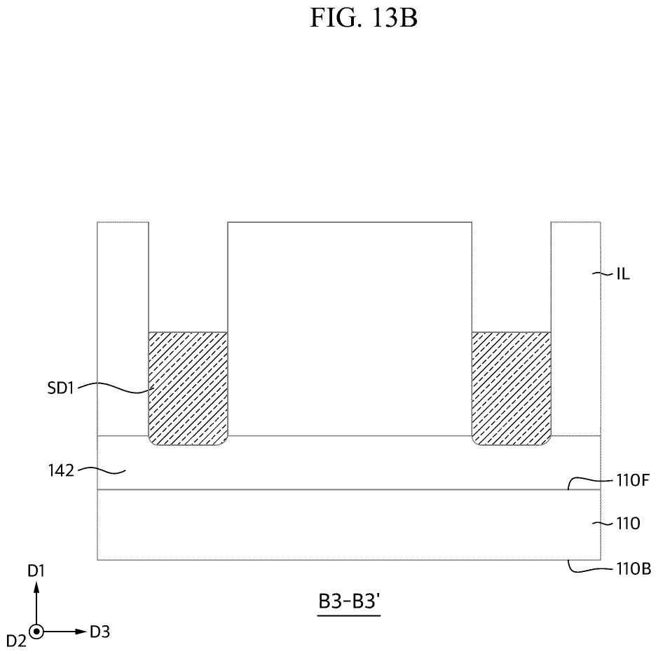

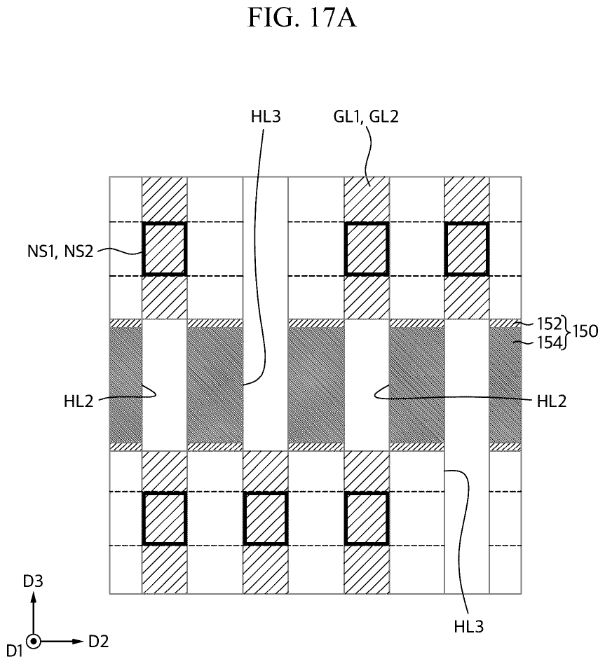

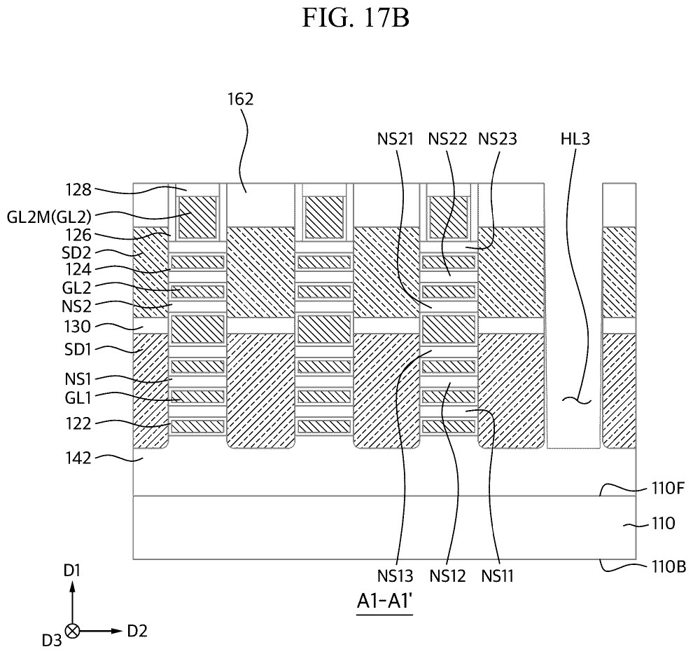

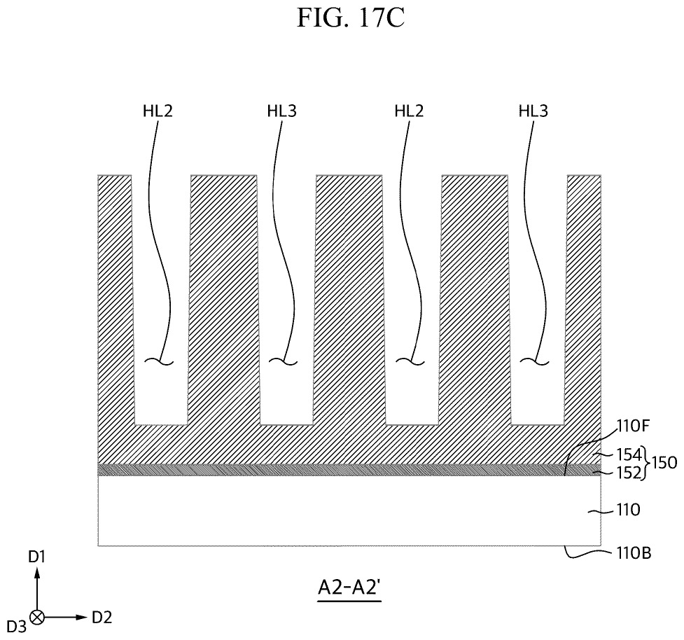

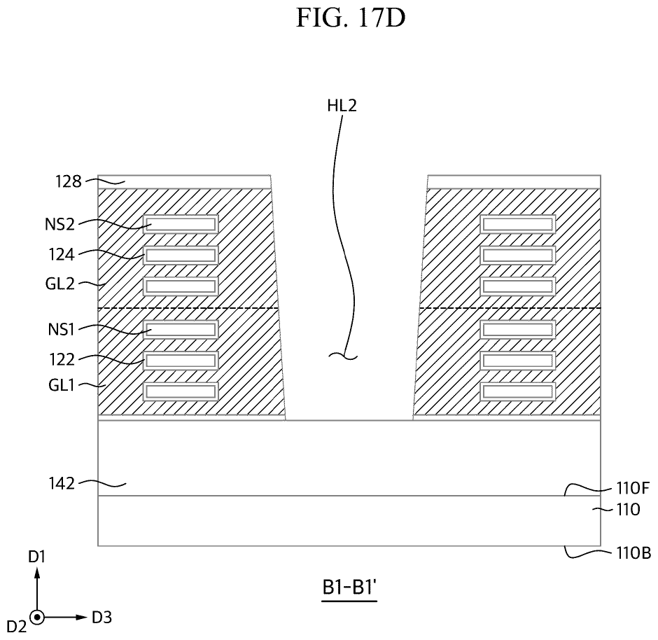

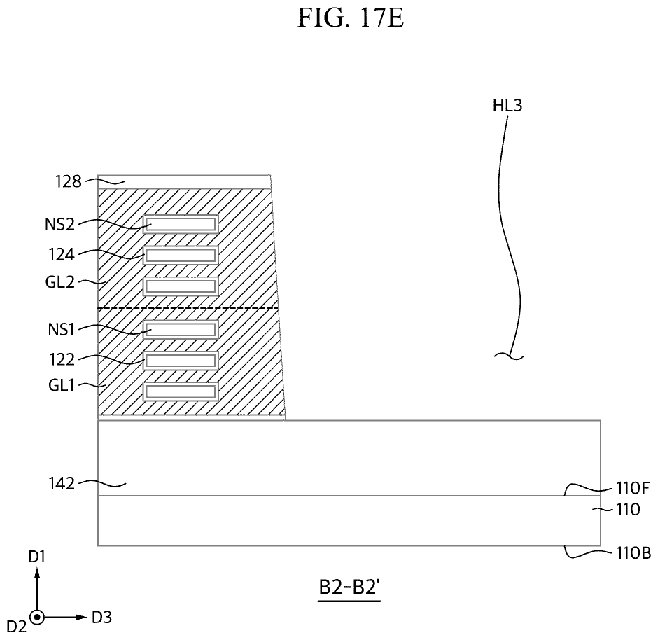

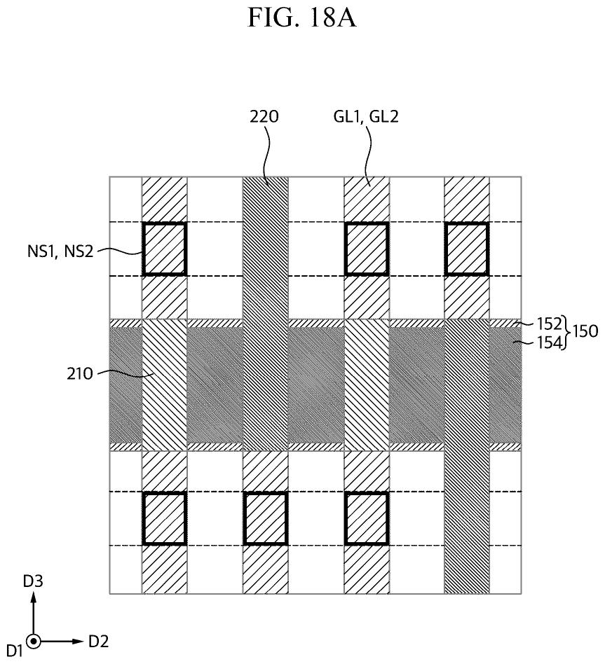

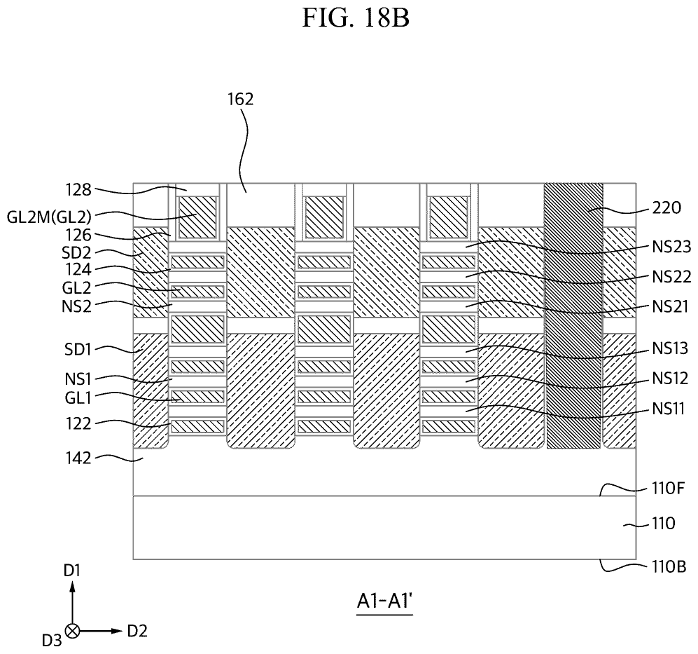

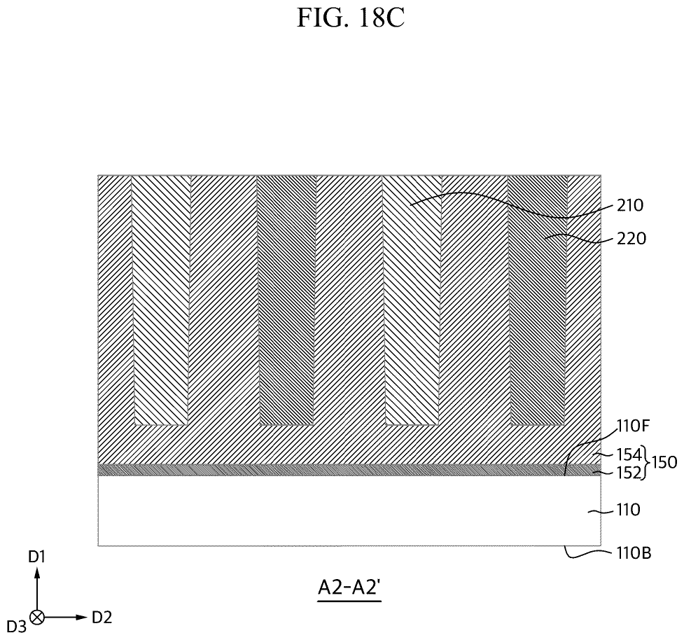

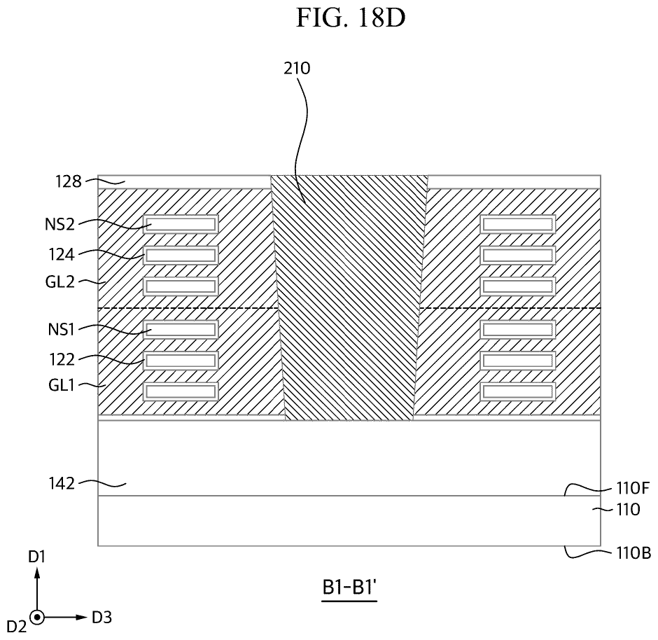

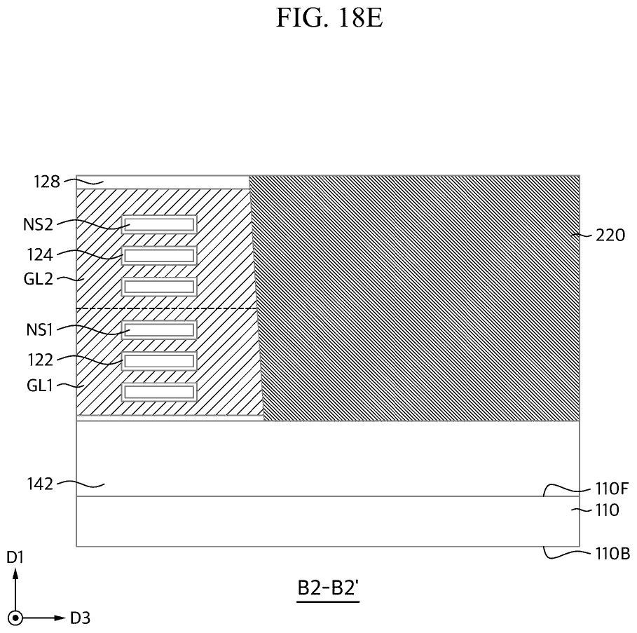

FIGS. 17E and 18E are diagrams corresponding to a cross section taken along line B2-B2′ of FIG. 1, and FIGS. 13B, 14B, 16C, 19C, 20C, 21C, 22B, 24B, and 25B.

### DETAILED DESCRIPTION

Hereinafter, the example embodiments of the present disclosure will be described with reference to the accompanying drawings. The same elements in the drawings will be denoted by the same reference numerals, and redundant descriptions therefor will be omitted.

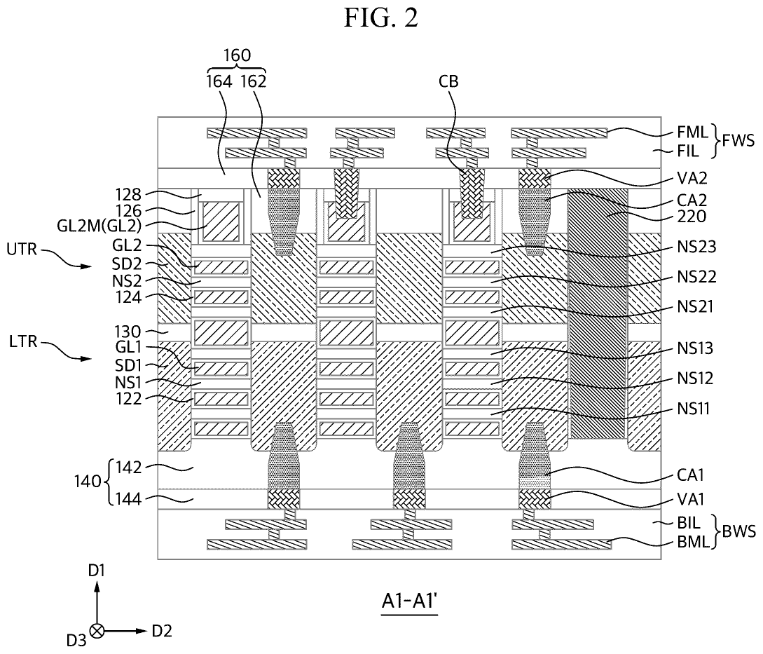

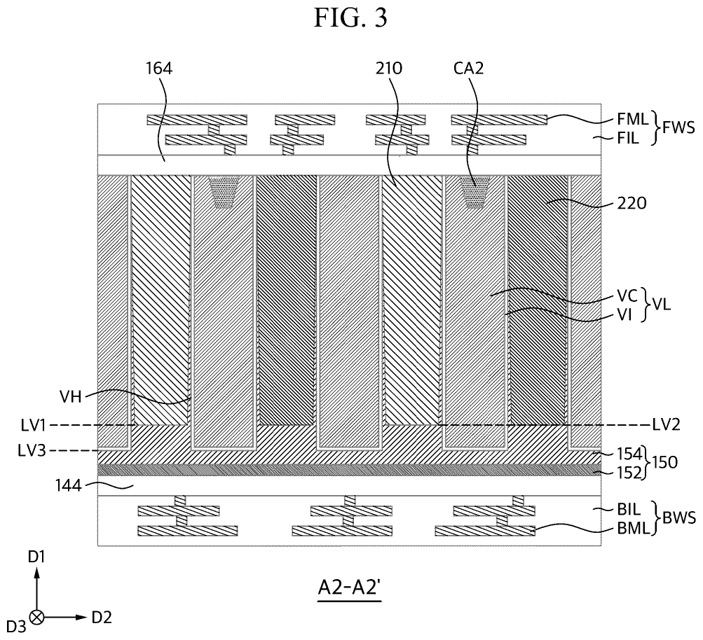

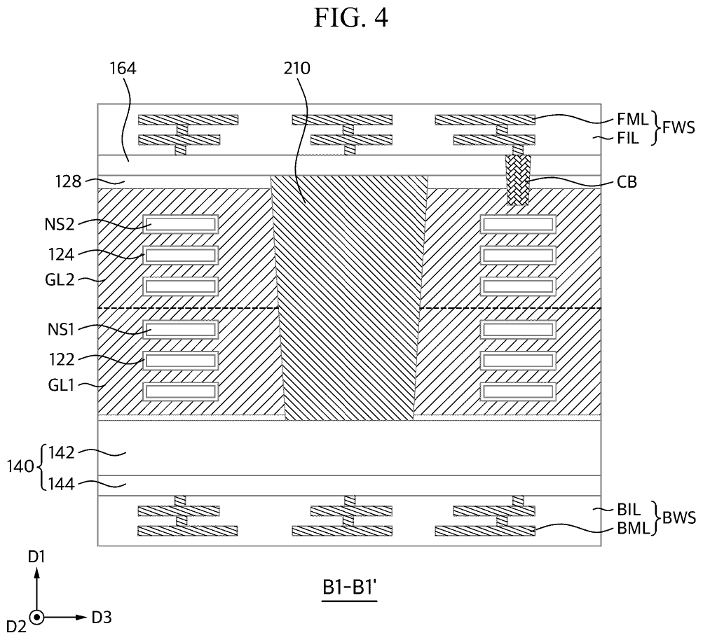

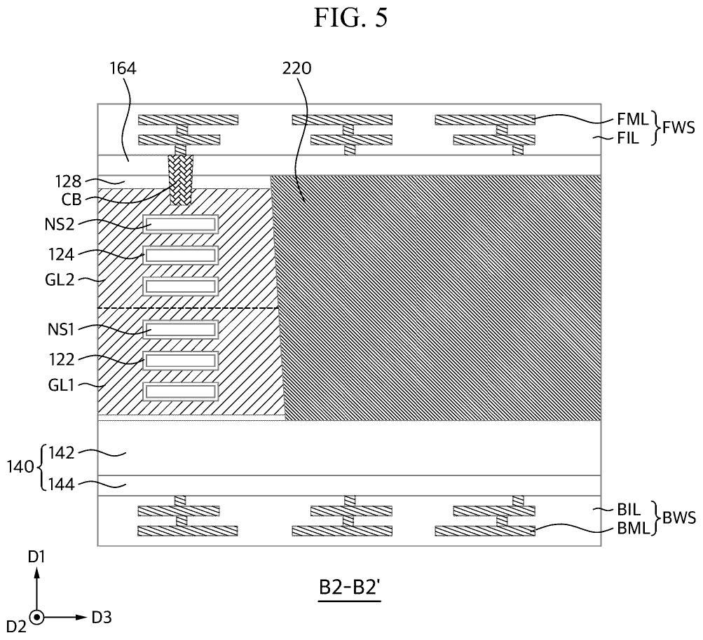

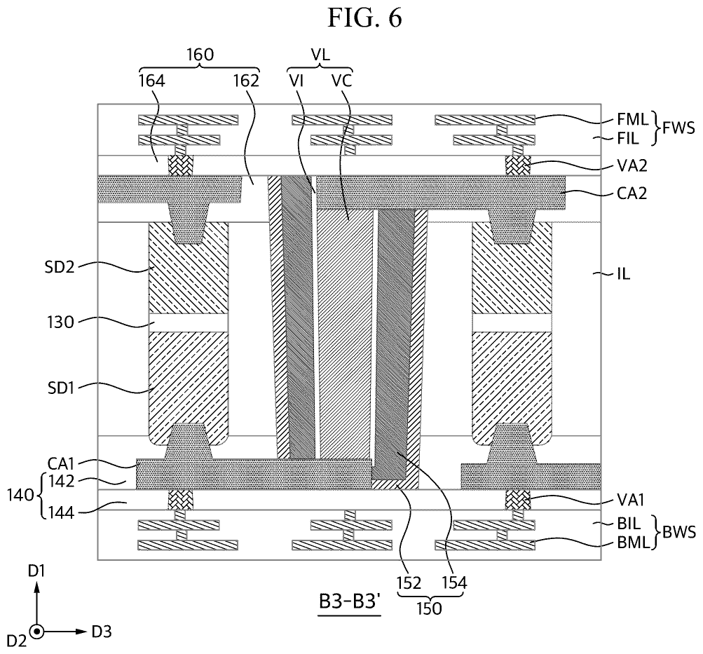

FIG. 1 is a schematic layout diagram illustrating an integrated circuit device according to an example embodiment of the present disclosure. FIG. 2 is an example diagram illustrating a cross section taken along line A1-A1′ of FIG. 1. FIG. 3 is an example diagram illustrating a cross section taken along line A2-A2′ of FIG. 1. FIG. 4 is an example diagram illustrating a cross section taken along line B1-B1′ of FIG. 1. FIG. 5 is an example diagram illustrating a cross section taken along line B2-B2′ of FIG. 1. FIG. 6 is an example diagram illustrating a cross section taken along line B3-B3′ of FIG. 1.

Referring to FIGS. 1 through 6, an integrated circuit device 10 may include a plurality of cells CR. Each of the cells CR may include a plurality of first transistors LTR and a plurality of second transistors UTR that are disposed at different levels in a first direction D1. In order to assist in understanding the present disclosure, a relative position in the first direction D1 may be shown as a vertically upper or lower position, and a relative position in a second direction D2 or a relative position in a third direction D3 may be shown as a laterally left or right position.

According to example embodiments, a first transistor LTR may be referred to as a lower transistor. A second transistor UTR may be referred to as an upper transistor. A first source/drain area SD1 may be referred to as a lower source/drain area. A second source/drain area SD2 may be referred to as an upper source/drain area. In addition, according to example embodiments of the present disclosure, a first gate line GL1 may be referred to as a lower gate line. A second gate line GL2 may be referred to as an upper gate line. A first gate insulation layer 122 may be referred to as a lower gate insulation layer. A second gate insulation layer 124 may be referred to as an upper gate insulation layer. Also, according to example embodiment of the present disclosure, a first contact CA1 may be referred to as a lower contact. A second contact CA2 may be referred to as an upper contact. A first via VA1 may be referred to as a lower via. A second via VA2 may be referred to as an upper via.

According to an example embodiment, the plurality of second transistors UTR may be disposed at a level higher in the first direction D1 than the plurality of first transistors LTR. Each of the plurality of cells CR may be an area in which various types of logic cells included in a logic circuit are disposed.

According to an example embodiment, the integrated circuit device 10 may further include a front-side wiring structure FWS disposed at a level higher in the first direction D1 than the plurality of second transistors UTR and a backside wiring structure BWS disposed at a level lower in the first direction D1 than the plurality of first transistors LTR. In example embodiments, the front-side wiring structure FWS may be configured to apply a signal voltage to the plurality of first transistors LTR and the plurality of second transistors UTR, and the backside wiring structure BWS may be configured to apply a power voltage and a ground voltage to the plurality of first transistors LTR and the plurality of second transistors UTR.

According to an example embodiment, the integrated circuit device 10 may form a logic cell including a multi-bridge channel field-effect transistor (MBCFET) device. However, the technical idea of the present disclosure is not limited thereto. The integrated circuit device 10 may include a planar field-effect transistor (planar FET) device, a gate-all-around-type FET device, a fin field-effect transistor (finFET) device, a FET device based on a two-dimensional material, such as a molybdenum disulfide (MoS2) semiconductor gate electrode, or the like.

According to an example embodiment, each of the plurality of first transistors LTR may include a plurality of lower nanosheets NS1 spaced apart in the first direction D1, the first source/drain area SD1 connected to the plurality of lower nanosheets NS1, the first gate line GL1 surrounding the plurality of lower nanosheets NS1, and the first contact CA1 disposed on a lower surface of the first source/drain area SD1.

According to an example embodiment, each of the plurality of second transistors UTR may include a plurality of upper nanosheets NS2 spaced apart in the first direction D1, the second source/drain area SD2 connected to the plurality of upper nanosheets NS2, the second gate line GL2 surrounding the plurality of upper nanosheets NS2, and the second contact CA2 disposed on an upper surface of the second source/drain area SD2.

According to an example embodiment, the plurality of first transistors LTR may be p-channel metal-oxide-semiconductor (PMOS) transistors, and the plurality of second transistors UTR may be n-channel metal-oxide-semiconductor (NMOS) transistors. According to an example embodiment, the plurality of first transistors LTR may be NMOS transistors, and the plurality of second transistors UTR may be PMOS transistors. In other example embodiments, the plurality of first transistors LTR may be NMOS transistors having a first threshold voltage, and the plurality of second transistors UTR may be NMOS transistors having a second threshold voltage different from the first threshold voltage. In other example embodiments, the plurality of first transistors LTR may be PMOS transistors having a first threshold voltage, and the plurality of second transistors UTR may be PMOS transistors having a second threshold voltage different from the first threshold voltage.

According to an example embodiment, the plurality of lower nanosheets NS1 and the plurality of upper nanosheets NS2 each may include a group IV semiconductor such as silicon (Si) or germanium (Ge), a group IV-IV compound semiconductor such as silicon germanium (SiGe) or silicon carbide (SiC), or a group III-V compound semiconductor such as gallium arsenide (GaAs), indium arsenide (InAs), or indium phosphide (InP). The plurality of lower nanosheets NS1 may include first to third lower nanosheets NS11, NS12, and NS13 spaced apart in the first direction D1. The plurality of upper nanosheets NS2 may include first to third upper nanosheets NS21, NS22, and NS23 spaced apart in the first direction D1.

According to an example embodiment, the first source/drain area SD1 may be connected to both side portions of the plurality of lower nanosheets NS1 in the second direction D2. In the present disclosure, the second direction D2 may be a direction in which the first source/drain area SD1 and the plurality of lower nanosheets NS1 are alternately disposed and that crosses the first direction D1. The first source/drain area SD1 may have an upper surface disposed at a level higher than an upper surface of an uppermost lower nanosheet NS1 (e.g., a third lower nanosheet NS13) and a lower surface disposed at a level lower than a lower surface of a lowermost lower nanosheet NS1 (e.g., a first lower nanosheet NS11). In example embodiments, the first source/drain area SD1 may include a doped silicon germanium (SiGe) film, a doped germanium (Ge) film, a doped silicon carbide (SiC) film, or a doped indium gallium arsenide (InGaAs) film, but it is merely an example.

According to an example embodiment, the first gate line GL1 may be extended in the third direction D3 to surround the plurality of lower nanosheets NS1. In this present disclosure, the third direction D3 may be a direction intersecting the first direction D1 and the second direction D2. A plurality of first gate lines GL1 may be provided. The plurality of first gate lines GL1 may be arranged to be spaced apart in the second direction D2. The first gate insulation layer 122 may be disposed between the first gate line GL1 and each of the plurality of lower nanosheets NS1 and between the first source/drain area SD1 and the first gate line GL1. As illustrated as an example in FIGS. 2 and 4, upper and lower surfaces and both side walls of each of the plurality of lower nanosheets NS1 may be surrounded by the first gate insulation layer 122 and the first gate line GL1.

According to an example embodiment, the second source/drain area SD2 may be connected to both side portions of the plurality of upper nanosheets NS2 in the second direction D2. The second source/drain area SD2 may be disposed to be spaced apart from the first source/drain area SD1 in the first direction D1 at a position overlapping the first source/drain area SD1 in the first direction D1. The second source/drain area SD2 may have an upper surface disposed at a level higher than an upper surface of an uppermost upper nanosheet NS2 (e.g., a third upper nanosheet NS23) and a lower surface disposed at a level lower than a lower surface of a lowermost upper nanosheet NS2 (e.g., a first upper nanosheet NS21). In example embodiments, the second source/drain area SD2 may include a doped silicon germanium (SiGe) film, a doped germanium (Ge) film, a doped silicon carbide (SiC) film, or a doped indium gallium arsenide (InGaAs) film, but it is merely an example.

According to an example embodiment, the second gate line GL2 may be extended in the third direction D3 to surround the plurality of upper nanosheets NS2. A plurality of second gate lines GL2 may be provided. The plurality of second gate lines GL2 may be spaced apart in the second direction D2. The second gate line GL2 may be disposed at a position overlapping the first gate line GL1 in the first direction D1. The second gate insulation layer 124 may be disposed between the second gate line GL2 and each of the plurality of upper nanosheets NS2 and between the second source/drain area SD2 and the second gate line GL2. As illustrated as an example in FIGS. 2 and 4, upper and lower surfaces and both side walls of each of the plurality of upper nanosheets NS2 may be surrounded by the second gate insulation layer 124 and the second gate line GL2.

According to an example embodiment, the second gate line GL2 may include a main gate portion GL2M disposed on an upper surface of the third upper nanosheet NS23. A spacer 126 may be disposed on both side walls of the main gate portion GL2M. A gate capping layer 128 may be disposed on an upper surface of the main gate portion GL2M. An upper gate insulation layer 124 may be disposed between a lower surface of the main gate portion GL2M and the third upper nanosheet NS23 and extended in the first direction D1 between the spacer 126 and the side walls of the main gate portion GL2M.

According to an example embodiment, the first gate line GL1 and the second gate line GL2 may be integrally formed to be electrically connected to each other. Thus, a voltage may be simultaneously applied to the first gate line GL1 and the second gate line GL2 through a gate contact CB. However, in other example embodiments, an insulation film may be provided between the first gate line GL1 and the second gate line GL2, so that the first gate line GL1 and the second gate line GL2 may be independently and electrically driven. Although not illustrated in the drawings, in this case, the insulation film may be provided between an upper surface of the first gate line GL1 and a lower surface of the second gate line GL2. According to independent and electric driving of the first gate line GL1 and the second gate line GL2, independent and electric driving of the first transistor LTR and the second transistor UTR may be implemented.

According to an example embodiment, the first gate line GL1 and the second gate line GL2 may include doped polysilicon, a metal, a conductive metallic nitride, a conductive metallic carbide, a conductive metallic silicide, or a combination thereof. For example, the first gate line GL1 and the second gate line GL2 may include aluminum (Al), copper (Cu), titanium (Ti), tantalum (Ta), tungsten (W), molybdenum (Mo), tantalum nitride (TaN), nickel silicide (NiSi), cobalt silicide (CoSi), titanium nitride (TiN), tungsten nitride (WN), titanium aluminide (TiAl), titanium aluminum nitride (TiAlN), tantalum carbonitirde (TaCN), tantalum carbide (TaC), tantallum silicon nitride (TaSiN), or a combination thereof, but it is merely an example. In example embodiments, the first gate line GL1 and the second gate line GL2 may include a work function metal-containing layer (not illustrated) and a gap-fill metallic film (not illustrated). The work function metal-containing layer may include at least one metal selected from titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), and palladium (Pd). The gap-fill metallic film may include a tungsten (W) film or an aluminum (Al) film. In example embodiments, the first gate line GL1 and the second gate line GL2 may include a stack structure of titanium aluminum carbide (TiAlC)/titanium nitride (TiN)/tungsten (W), a stack structure of titanium nitride (TiN)/tantalum nitride (TaN)/titanium aluminum carbide (TiAlC)/titanium nitride (TiN)/tungsten (W), or a stack structure of titanium nitride (TiN)/tantalum nitride (TaN)/titanium nitride (TiN)/titanium aluminum carbide (TiAlC)/titanium nitride (TiN)/tungsten (W), but it is merely an example.

According to an example embodiment, a lower gate insulation layer 122 and the upper gate insulation layer 124 may include a silicon oxide film, a silicon oxynitride film, a high-dielectric film having a dielectric constant higher than that of a silicon oxide film, or a combination thereof. The high-dielectric film may include a metallic oxide or a metallic oxynitride. For example, the high-dielectric film which may be used as the lower gate insulation layer 122 and the upper gate insulation layer 124 may include hafnium dioxide (HfO2), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), zirconium dioxide (ZrO2), aluminum oxide (Al2O3), or a combination thereof, but it is merely an example.

According to an example embodiment, the spacer 126 may include silicon oxide (SiOx), silicon nitride (SiNx), silicon oxynitride (SiOxNy), silicon carbonitride (SiCxNy), silicon oxycarbonitride(SiOxCyNz), or a combination thereof. In example embodiments, the gate capping layer 128 may include silicon nitride or silicon oxynitride.

According to an example embodiment, the first contact CA1 may be disposed on the lower surface of the first source/drain area SD1 (for example, as illustrated in FIG. 2, below the first source/drain area SD1 or at a level lower in the first direction D1 than the first source/drain area SD1). According to an example embodiment, the second contact CA2 may be disposed on the upper surface of the second source/drain area SD2 (for example, as illustrated in FIG. 2, at a level higher in the first direction D1 than the first source/drain area SD1). In example embodiments, the first contact CA1 and the second contact CA2 may include at least one of tungsten (W), cobalt (Co), molybdenum (Mo), nickel (Ni), ruthenium (Ru), copper (Cu), aluminum (Al), titanium (Ti), titanium nitride (TiN), tantalum (Ta), tantalum nitride (TaN), titanium silicon nitride (TiSiN), titanium silicide (TiSi), or tungsten silicide (WSi).

According to an example embodiment, the integrated circuit device 10 may include a separation part 130 physically separating the first source/drain area SD1 and the second source/drain area SD2. The separation part 130 may electrically separate the first source/drain area SD1 and the second source/drain area SD2. For example, the separation part 130 between the first gate line GL1 and the second gate line GL2 may electrically separate the first source/drain area SD1 and the second source/drain area SD2. The separation part 130 may serve as an insulation film between the first source/drain area SD1 and the second source/drain area SD2.

According to an example embodiment, a conductive rail VL may be extended in the first direction D1 between two first transistors LTR disposed to be adjacent in the third direction D3 and between two second transistors UTR disposed to be adjacent in the third direction D3. A plurality of conductive rails VL may be provided. As illustrated in FIG. 1, the plurality of conductive rails VL may be disposed to be spaced apart from each other in the second direction D2. The conductive rail VL may be disposed in a via trench VH extended in the first direction D1. According to an example embodiment, the conductive rail VL may not overlap a first diffusion breaker 210 and a second diffusion breaker 220 in the third direction D3.

According to an example embodiment, the conductive rail VL may be a wiring structure for transmitting the signal voltage, the power voltage, the ground voltage, or the like from the front-side wiring structure FWS and the backside wiring structure BWS to the first transistor LTR and the second transistor UTR.

According to an example embodiment, the conductive rail VL may include a conductor VC and an insulation liner VI. The insulation liner VI may be extended to be conformal on an inner wall of the vertical via trench VH. The conductor VC may fill, on the insulation liner VI, a space in the vertical via trench VH.

In an example embodiment, the vertical via trench VH may have a side wall sloped so that a width of an upper portion is larger than a width of a lower portion. The conductive rail VL disposed in the vertical via trench VH may also have a side sloped so that a width of an upper portion is larger than a width of a lower portion.

In an example embodiment, the conductive rail VL may be electrically connected to a second contact CA2 adjacent to the conductive rail VL among a plurality of second contacts CA2. The second contact CA2 may be connected by penetrating at least a portion of the conductive rail VL. In such an example embodiment, the conductive rail VL may function as a conductive via for electrically connecting the second contact CA2 to the backside wiring structure BWS. In another example embodiment, the conductive rail VL may function as a conductive via for electrically connecting the second contact CA1 to the front-side wiring structure FWS.

According to an example embodiment, a backside insulation structure 140 may be disposed on the lower surface of the first source/drain area SD1 and below a lower surface of a lower nanosheet NS1 (as illustrated in FIG. 2, below the first source/drain area SD1 and the lower nanosheet NS1). The backside insulation structure 140 may include a first base insulation layer 142 and a second base insulation layer 144. The first base insulation layer 142 may be disposed on the lower surface of the first source/drain area SD1 and below the lower surface of the lower nanosheet NS1. The second base insulation layer 144 may be disposed on a lower surface of the first base insulation layer 142 (as illustrated in FIG. 2, below the first base insulation layer 142).

According to an example embodiment, the first via VA1 may be electrically connected to the first contact CA1 by penetrating the second base insulation layer 144.

According to an example embodiment, the backside wiring structure BWS may be disposed on a lower surface of the backside insulation layer structure 140 (as illustrated in FIG. 2, below the backside insulation structure 140. The backside wiring structure BWS may include a first wiring line BML and a first cover insulation layer BIL. The first wiring line BML may include a plurality of conductive patterns disposed at different vertical levels and a plurality of conductive vias for interconnection thereof. The first cover insulation layer BIL may include a plurality of insulation layers surrounding the plurality of conductive patterns and the plurality of conductive vias.

According to an example embodiment, a front-side insulation structure 160 may be disposed on the upper surface of the second source/drain area SD2 and above the second gate line GL2. The backside insulation structure 160 may include a first insulation layer 162 and a second insulation layer 164. The first insulation layer later 162 may cover an upper portion of the second source/drain area SD2 and a side wall of the spacer 126. The second insulation layer 164 may be disposed on the first insulation layer 162, the spacer 126, the gate capping layer 128, the second contact CA2, the first diffusion breaker 210, and the second diffusion breaker.

According to an example embodiment, the second via VA2 may be electrically connected to the second contact CA2 by penetrating the second insulation layer 164. The gate contact CB may be disposed to be connected to the second gate line GL2 by penetrating the second insulation layer 264 and the gate capping layer 128. The second contact CA2 may be disposed to be connected to the second source/drain area SD2 by penetrating the first insulation layer 162.

According an example embodiment, the front-side wiring structure FWS may be disposed on an upper surface of the front-side insulation structure 160. The front-side wiring structure FWS may include a second wiring line FML and a second cover insulation layer FIL. The second wiring line FML may include a plurality of conductive patterns disposed at different vertical levels and a plurality of conductive vias for interconnection thereof. The second cover insulation layer FIL may include a plurality of insulation layers surrounding the plurality of conductive patterns and the plurality of conductive vias.

According to an example embodiment, the first contact CA1, the second contact CA2, the gate contact CB, the first via VA1, and the second via VA2 may include a metal, for example, copper (Cu), aluminum (Al), or tungsten (W), but it is merely an example.

According to an example embodiment, the first wiring line BML and the second wiring line FML may include a metal, for example, copper (Cu), aluminum (Al), or tungsten (W), but it is merely an example. A barrier film may be interposed between the first wiring line BML and the first cover insulation layer BIL or between the second wiring line FML and the cover insulation layer FIL. A thickness of the barrier film may be 50 to 1000 angstroms (Å). The barrier film may include titanium (Ti), tantalum (Ta), titanium nitride (TiN), or tantalum nitride (TaN). The first cover insulation layer BIL and the second cover insulation layer FIL may include silicon oxide, silicon nitride, silicon oxynitride, an insulation material having permittivity lower than that of silicon oxide, or a combination thereof. In some example embodiments, the first cover insulation layer BIL and the second cover insulation layer FIL may include a tetraethyl orthosilicate (TEOS) film or an ultra-low K (ULK) film having an ultra-low dielectric constant K of approximately 2.2 to 2.4. The ULK film may include a silicon oxycarbide (SiOC) film or a hydrogenated silicon carbon oxide film (SiCOH).

According to an example embodiment, the first diffusion breaker 210 may be disposed beside the conductive rail VL in the second direction D2. The plurality of conductive rails VL may be provided. The first diffusion breaker 210 may be disposed between a pair of adjacent conductive rails VL among the plurality of conductive rails VL spaced apart in the second direction D2. The first diffusion breaker 210 may be embedded in the gate separation structure 150. A portion of the first diffusion breaker 210 may be embedded in a gate separation oxide film 154, and a lower surface of the first diffusion breaker 210 may be positioned to be spaced apart from a gate separation liner 152 in the first direction D1. According to an example embodiment, the first diffusion breaker 210 may completely overlap the gate separation structure 150 in the second direction D2. Both side walls of the first diffusion breaker 210, which cross the third direction D3, may be aligned to both side walls of the gate separation liner 152, which cross the third direction D3.

According to an example embodiment, as illustrated in FIG. 4, the first diffusion breaker 210 may be in contact with the first gate line GL1 and the gate line GL2. The first diffusion breaker 210 may serve as a gate cut of the first gate line GL1 and the second gate line GL2 which are extended in the third direction D3. In other words, the first diffusion breaker 210 may serve to electrically insulate the first gate lines GL1 and the second gate lines GL2, which are spaced apart in the third direction D3, from each other. The first diffusion breaker 210 may have a tapered shape of which a width is narrowed in a direction from an upper portion (namely, a portion at a level high in the first direction D1) to a lower portion (namely, a portion at a level low in the first direction D1). However, it is merely an example. In some example embodiments, the first diffusion breaker 210 may have a shape having a width constant in the first direction D1.

According to an example embodiment, the first diffusion breaker 210 or the second diffusion breaker 220 may be interposed between the plurality of first gate lines GL1 spaced apart in the third direction D3, and through this, the conductive rail VL may not be in contact with the plurality of first gate lines GL1. That is, the first diffusion breaker 210 and the second diffusion breaker 220 may serve as an insulator that prevents a short circuit between the first gate line GL1 and the conductive rail VL. Similarly, the first diffusion breaker 210 or the second diffusion breaker 220 may be interposed between the plurality of second gate lines GL2 spaced apart in the third direction D3, and through this, the conductive rail VL may not be in contact with the plurality of second gate lines GL2. In other words, the first diffusion breaker 210 and the second diffusion breaker 220 may serve as an insulator that prevents a short circuit between the second gate line GL2 and the conductive rail VL.

According to an example embodiment, the second diffusion breaker 220 may be disposed beside the conductive rail VL in the second direction D2. The plurality of conductive rails VL may be provided. The second diffusion breaker 220 may be disposed between a pair of adjacent conductive rails VL among the plurality of conductive rails VL spaced apart in the second direction D2. A portion of the second diffusion breaker 220 may be embedded in the second direction D2 in the gate separation structure 150. The portion of the second diffusion breaker 220 may be embedded in the gate separation oxide film 154 and positioned to be spaced apart from the gate separation liner 152 in the first direction D1. According to an example embodiment, a portion of the second diffusion breaker 220 may overlap the gate separation structure 150 in the second direction D2. That is, one side wall of the first diffusion breaker 210, which crosses the third direction D3, may be aligned to a side wall of the gate separation liner 152, which crosses the third direction D3.

According to an example embodiment, as illustrated in FIG. 5, the second diffusion breaker 220 may be in contact with the first gate line GL1 and the gate line GL2. The second diffusion breaker 220 may serve as a gate cut of the first gate line GL1 and the second gate line GL2 which are extended in the third direction D3. In other words, the second diffusion breaker 220 may serve to electrically insulate the first gate lines GL1 and the second gate lines GL2, which are spaced apart in the third direction D3, from each other. The second diffusion breaker 220 may have a tapered shape of which a width is narrowed in a direction from an upper portion (namely, a portion at a level high in the first direction D1) to a lower portion (namely, a portion at a level low in the first direction D1). However, it is merely an example. In some example embodiments, the second diffusion breaker 220 may have a shape having a width constant in the first direction D1.

According to an example embodiment, a lower surface of the first lower nanosheet NS11 and lower surfaces of the first diffusion breaker 210 and the second diffusion breaker 220 may be positioned on an identical plane. In some example embodiments, the lower surfaces of the first diffusion breaker 210 and the second diffusion breaker 220 may be positioned at a level lower in the first direction D1 than the lower surface of the first lower nanosheet NS11.

According to an example embodiment, upper surfaces of the first diffusion breaker 210, the second diffusion breaker 220, and the plurality of conductive rails VL may be positioned on an identical plane or may be coplanar with each other.

According to an example embodiment, the first diffusion breaker 210 and the second diffusion breaker 220 may include an insulation material. According to an example embodiment, the first diffusion breaker 210 and the second diffusion breaker 220 may include an insulation material such as a silicon oxide film or a silicon nitride film.

According to an example embodiment, the lower surface of the fist diffusion breaker 210 may have a first level LV1 in the first direction D1. A lower surface of the second diffusion breaker 220 may have a second level LV2 in the first direction D1. A lower surface of the conductive rail VL may have a third level LV3 in the first direction D1. The first level LV1 of the lower surface of the first diffusion breaker 210 may be substantially equal to the second level LV2 of the lower surface of the second diffusion breaker 220. Also, the third level LV3 of the conductive rail VL may be positioned at a level lower than the first level LV1 of the lower surface of the first diffusion breaker 210 and the second level LV2 of the lower surface of the second diffusion breaker 220.

As used herein, the expression “substantially equal” may refer to having the same value relative to other value(s) compared therewith, as will be appreciated by those of skill in the art, and allows for approximations, inaccuracies and limits of measurement under the relevant circumstances. In one or more aspects, the terms “substantially,” “about,” and “approximately” may provide an industry-accepted tolerance for their corresponding terms and/or relativity between items, such as a tolerance of ±1%, ±5%, or ±10% of the actual value stated, and other suitable tolerances.

According to an example embodiment, the integrated circuit device 10 may have a three-dimensional field-effect transistor structure in which the first transistor LTR and the second transistor UTR are disposed to be spaced apart in the first direction D1, and the conductive rail VL may connect the backside wiring structure BWS which is connected to the first transistor LTR and the front-side wiring structure FWS which is connected to the second transistor UTR.

According to an example embodiment, an upper surface of the first diffusion breaker 210, an upper surface of the second diffusion breaker 220, and an uppermost surface of the conductive rail VL all may be positioned on an identical plane. As described below, the conductive rail VL may be formed in a self-align scheme between the first diffusion breaker 210 and the second diffusion breaker 220, and then a planarization process may be performed. According to the planarization process, the upper surface of the first diffusion breaker 210, the upper surface of the second diffusion breaker 220, and the uppermost surface of the conductive rail VL all may be positioned on the identical plane.

According to an example embodiment, the first diffusion breaker 210 and the second diffusion breaker 220 which have an etch selectivity for the gate separation oxide film 154 may be provided, so that the conductive rail VL may be formed in the self-align scheme between the first diffusion breaker 210 and the second diffusion breaker 220. As described below, the first diffusion breaker 210 and the second diffusion breaker 220 may be formed to be spaced apart in the second direction D2 in the gate separation oxide film 154. The first diffusion breaker 210 and the second diffusion breaker 220 may have the etch selectivity for the gate separation oxide film 154. After the first diffusion breaker 210 and the second diffusion breaker 220 are formed in the gate separation oxide film 154, an etching process may be performed for the gate separation oxide film 154 between the first diffusion breaker 210 and the second diffusion breaker 220, so that the via trench VH may be formed. At this point, since the first diffusion breaker 210 and the second diffusion breaker 220 have the etch selectivity for the gate separation oxide film 154, the via trench VH may be formed as the gate separation oxide film 154 is etched, but the first diffusion breaker 210 and the second diffusion breaker 220 may be approximately not etched. Afterward, the insulation liner VI and the conductor VC may be formed in the via trench VH, so that the conductive rail VL may be completed. Through the series of processes described above, the conductive rail VL may be formed through the etching process without a photomask.

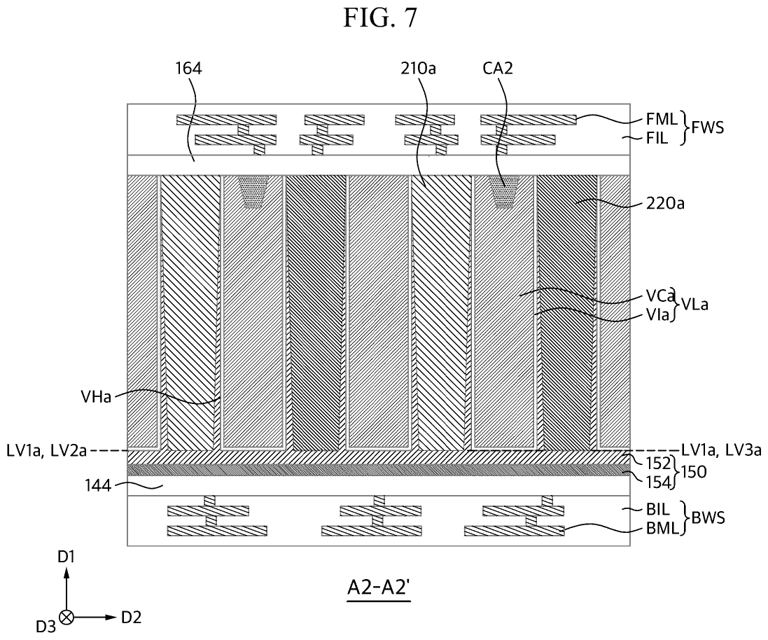

FIG. 7 is a diagram illustrating a cross section of an integrated circuit device 20 according to another example embodiment of the present disclosure and an example diagram corresponding to FIG. 3.

The integrated circuit device 20 which is illustrated in FIG. 7 may be approximately identical or similar to the integrated circuit device 10 which is illustrated in FIGS. 1 through 6 except that levels of lower surfaces of a first diffusion breaker 210a and a second diffusion breaker 220a in the first direction D1 are equal to a level of a lower surface of a conductive rail VLa in the first direction D1. Thus, a description of the element described above with reference to FIGS. 1 through 6 will be omitted or simplified below.

According to an example embodiment, a lower surface of the fist diffusion breaker 210a may have a first level LV1a in the first direction D1. A lower surface of the second diffusion breaker 220a may have a second level LV2a in the first direction D1. The lower surface of the conductive rail VLa may have a third level LV3a in the first direction D1. The first level LV1a of the lower surface of the first diffusion breaker 210a may be substantially equal to the second level LV2a of the lower surface of the second diffusion breaker 220a. Also, the third level LV3a of the conductive rail VLa may be substantially equal to the first level LV1a of the lower surface of the first diffusion breaker 210a and the second level LV2a of the lower surface of the second diffusion breaker 220.

According to an example embodiment, the first diffusion breaker 210a and the second diffusion breaker 220a which have an etch selectivity for the gate separation oxide film 154 may be provided, so that the conductive rail VLa may be formed in a self-align scheme between the first diffusion breaker 210a and the second diffusion breaker 220a. After the first diffusion breaker 210a and the second diffusion breaker 220a are formed in the gate separation oxide film 154, an etching process may be performed for the gate separation oxide film 154 between the first diffusion breaker 210a and the second diffusion breaker 220a, so that the via trench VH may be formed. In a process of forming the via trench VH by etching the gate separation oxide film 154, a level of a lower surface of the via trench VH may be formed to be equal to the first level LV1a of the first diffusion breaker 210a and the second level LV2a of the second diffusion breaker 220a.

The lower surface of the first diffusion breaker 210a and the lower surface of the second diffusion breaker 220a may be positioned at a level equal to that of the lower surface of the vertical rail VLa. Through this, referring to FIGS. 1 and 7 together, the vertical rail VLa may completely overlap both of the first diffusion breaker 210a and the second diffusion breaker 220a in the second direction D2.

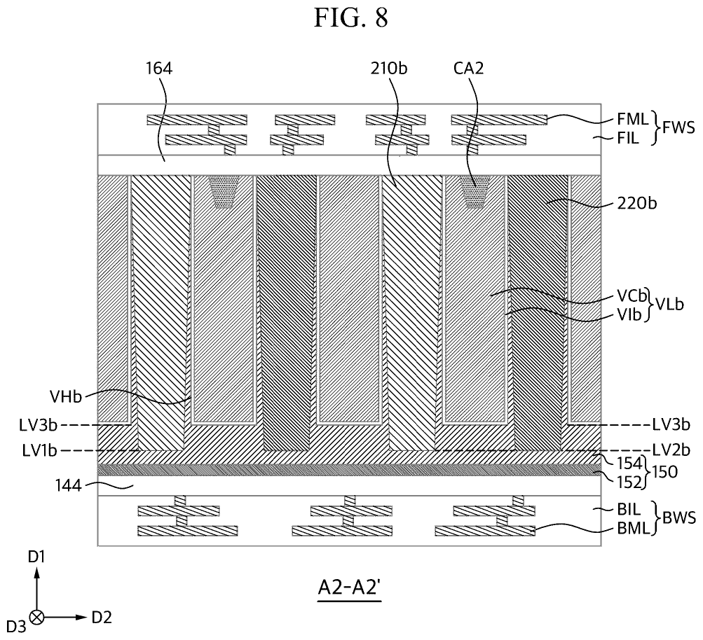

FIG. 8 is a diagram illustrating a cross section of an integrated circuit device 30 according to another example embodiment of the present disclosure and an example diagram corresponding to FIG. 3.

The integrated circuit device 30 which is illustrated in FIG. 8 may be approximately identical or similar to the integrated circuit device 10 which is illustrated in FIGS. 1 through 6 except that levels of lower surfaces of a first diffusion breaker 210b and a second diffusion breaker 220b in the first direction D1 are equal to a level of a lower surface of a conductive rail VLb in the first direction D1. Thus, a description of the element described above with reference to FIGS. 1 through 6 will be omitted or simplified below.

According to an example embodiment, a lower surface of the fist diffusion breaker 210b may have a first level LV1b in the first direction D1. A lower surface of the second diffusion breaker 220b may have a second level LV2b in the first direction D1. The lower surface of the conductive rail VLb may have a third level LV3b in the first direction D1. The first level LV1b of the lower surface of the first diffusion breaker 210b may be substantially equal to the second level LV2b of the lower surface of the second diffusion breaker 220b. Also, the third level LV3b of the conductive rail VLb may be higher than the first level LV1b of the lower surface of the first diffusion breaker 210b and the second level LV2b of the lower surface of the second diffusion breaker 220b.

According to an example embodiment, the first diffusion breaker 210b and the second diffusion breaker 220b which have an etch selectivity for the gate separation oxide film 154 may be provided, so that the conductive rail VLb may be formed in a self-align scheme between the first diffusion breaker 210b and the second diffusion breaker 220b. After the first diffusion breaker 210b and the second diffusion breaker 220b are formed in the gate separation oxide film 154, an etching process may be performed for the gate separation oxide film 154 between the first diffusion breaker 210b and the second diffusion breaker 220b, so that the via trench VH may be formed. In a process of forming the via trench VH by etching the gate separation oxide film 154, a level of a lower surface of the via trench VH may be formed to be higher than the first level LV1b of the first diffusion breaker 210b and the second level LV2b of the second diffusion breaker 220b.

The first level LV1b of the lower surface of the first diffusion breaker 210b and the second level LV2b of the lower surface of the second diffusion breaker 220b may be positioned to be lower than the third level LV3b of the lower surface of the vertical rail VLb. Through this, referring to FIGS. 1 and 8 together, the vertical rail VLb may completely overlap both of the first diffusion breaker 210b and the second diffusion breaker 220b in the second direction D2.

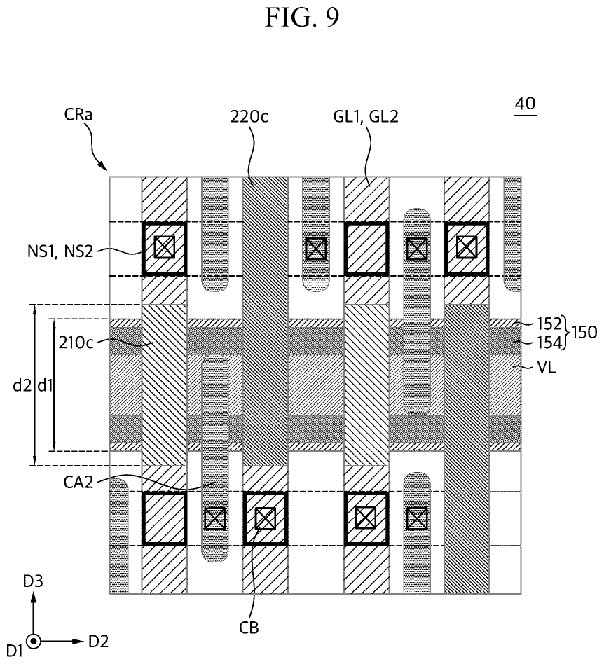

FIG. 9 is a schematic layout diagram illustrating an integrated circuit device 40 according to another example embodiment of the present disclosure.

The integrated circuit device 40 illustrated in FIG. 9 may be approximately identical or similar to the integrated circuit device 10 which is illustrated in FIGS. 1 through 6 except that a length d1 of the gate separation structure 150 in the third direction D3 is shorter than a length d2 of a first diffusion breaker 210c in the third direction D3. Thus, a description of the element described above with reference to FIGS. 1 through 6 will be omitted or simplified below.

Referring to FIG. 9, the integrated circuit device 40 may include a plurality of cells CRa. Each of the plurality of cells CRa may include the first diffusion breaker 210c and a second diffusion breaker 220c which are extended in the first direction D1 and the third direction D3. In addition, each of the plurality of cells CRa may include the plurality of conductive rails VL which is arranged to be spaced apart in the second direction D2.

According to an example embodiment, a length d2 of the first diffusion breaker 210c in the third direction D3 may be longer than the length d1 of the gate separation structure 150 in the third direction D3. At this point, the first diffusion breaker 210c may overlap the gate separation structure 150 in the second direction D2. Specifically, when viewed from above in the first direction D1, the gate separation structure 150 may completely overlap a portion of the first diffusion breaker 210c in the second direction D2.

According to an example embodiment, the first diffusion breaker 210c may overlap the conductive rail VL in the second direction D2. Specifically, the conductive rail VL may completely overlap a portion of the first diffusion breaker 210c in the second direction D2. When viewed from above in the first direction D1, both side walls of the first diffusion breaker 210c, which cross the third direction D3, may protrude from side walls of the gate separation liner 152, which cross the third direction D3, in the third direction D3. In addition, one side wall of the first diffusion breaker 210c, which crosses the third direction D3, may protrude from a side wall of the gate separation liner 152, which crosses the third direction D3, in the third direction D3.

According to an example embodiment, one side wall among the both side walls of the first diffusion breaker 210c, which cross the third direction D3, and a side wall of the second diffusion breaker 220c, which crosses the third direction D3, may be positioned on an identical plane. However, it is merely an example. In some example embodiments, the one side wall of the first diffusion breaker 210c, which crosses the third direction D3, may be positioned at a level different in the third direction D3 from that of the side wall of the second diffusion breaker 220c, which crosses the third direction D3.

According to an example embodiment, with the first diffusion breaker 210c and the second diffusion breaker 220c as a boundary, the plurality of conductive rails VL may be electrically insulated from each other.

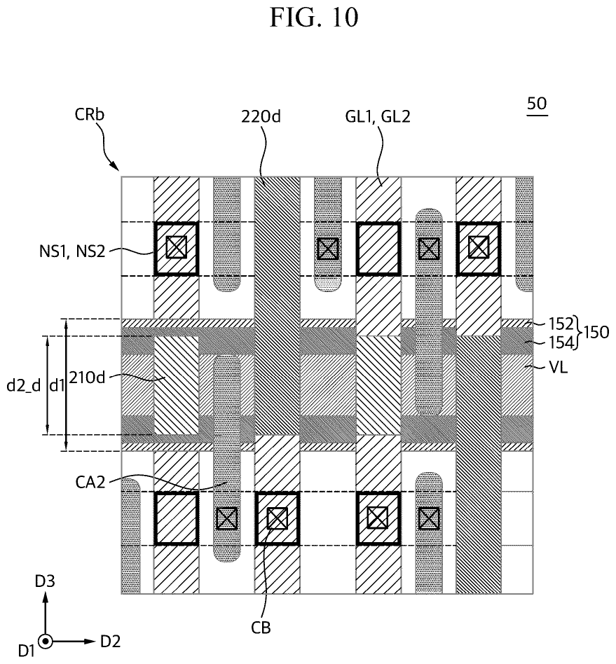

FIG. 10 is a schematic layout diagram illustrating an integrated circuit device 50 according to another example embodiment of the present disclosure.

The integrated circuit device 50 illustrated in FIG. 10 may be approximately identical or similar to the integrated circuit device 10 which is illustrated in FIGS. 1 through 6 except that the length d1 of the gate separation structure 150 in the third direction D3 is shorter than a length d2_d of a first diffusion breaker 210d in the third direction D3. Thus, a description of the element described above with reference to FIGS. 1 through 6 will be omitted or simplified below.

Referring to FIG. 10, the integrated circuit device 50 may include a plurality of cells CRb. Each of the plurality of cells CRb may include the first diffusion breaker 210d and a second diffusion breaker 220d which are extended in the first direction D1 and the third direction D3. In addition, each of the plurality of cells CRa may include the plurality of conductive rails VL which is arranged to be spaced apart in the second direction D2.

According to an example embodiment, the length d2_d of the first diffusion breaker 210d in the third direction D3 may be shorter than the length d1 of the gate separation structure 150 in the third direction D3. At this point, the first diffusion breaker 210d may overlap a portion of the gate separation oxide film 154 in the second direction D2. However, the first diffusion breaker 210d may not overlap the gate separation liner 152 in the second direction D2. According to an example embodiment, the first diffusion breaker 210d may overlap the conductive rail VL in the second direction D2. Specifically, when viewed from above in the first direction D1, the conductive rail VL may completely overlap a portion of the first diffusion breaker 210d in the second direction D2.

According to an example embodiment, one side wall among both side walls of the first diffusion breaker 210d, which cross the third direction D3, and a side wall of the second diffusion breaker 220d, which crosses the third direction D3, may be positioned on an identical plane. However, it is merely an example. In some example embodiments, the one side wall of the first diffusion breaker 210d, which crosses the third direction D3, may be positioned at a level different in the third direction D3 from that of the side wall of the second diffusion breaker 220d, which crosses the third direction D3.

According to an example embodiment, with the first diffusion breaker 210d and the second diffusion breaker 220d as a boundary, the plurality of conductive rails VL may be electrically insulated from each other.

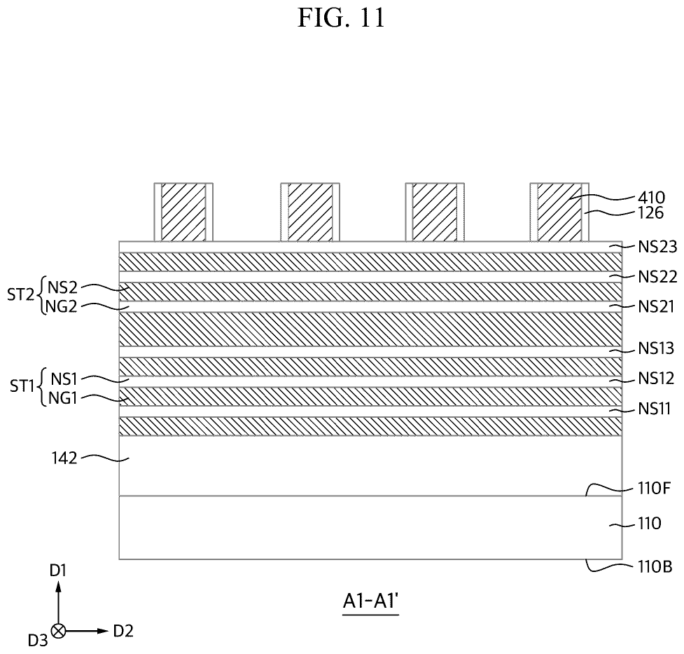

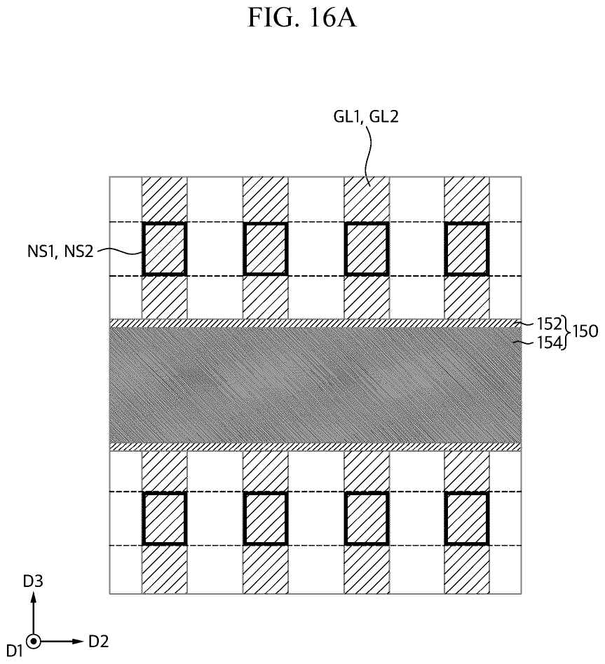

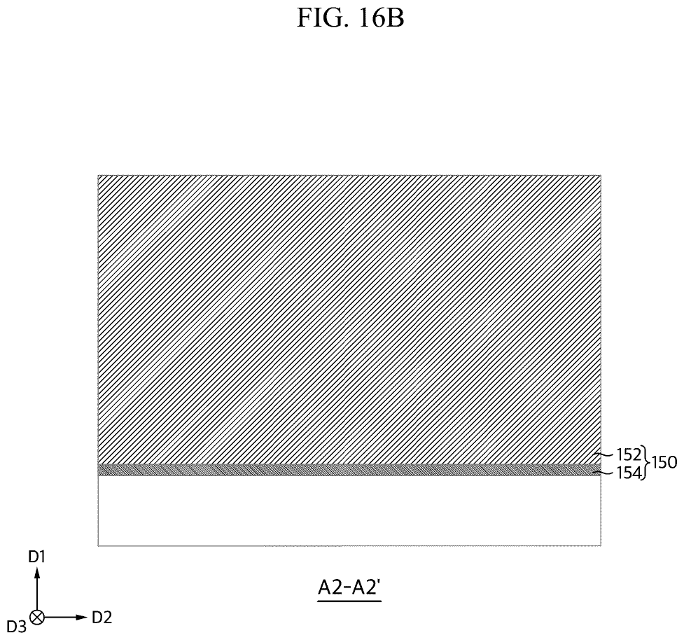

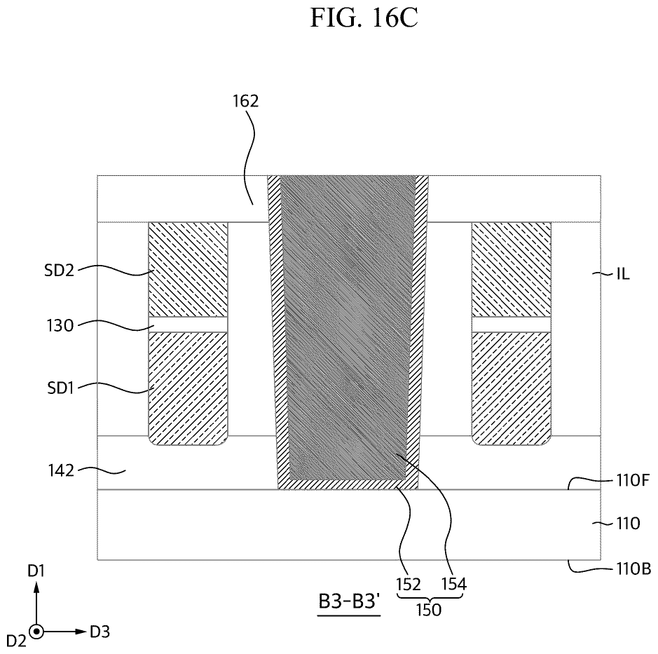

FIGS. 11, 12, 13A, 13B, 14A, 14B, 15A, 15B, 15C, 16A, 16B, 16C, 17A, 17B, 17C, 17D, 17E, 18A, 18B, 18C, 18D, 18E, 19A, 19B, 19C, 20A, 20B, 21A, 21B, 21C, 22A, 22B, 23, 24A, 24B, 25A, and 25B are cross-sectional diagrams illustrating, in process order, a method of manufacturing an integrated circuit device according to an example embodiment of the present disclosure. FIGS, 15A, 16A, 18A, 20A, and 21A are layout diagrams. FIGS. 11, 12, 13A, 14A, and 15B, 17B, 18B, 22A, 23. 24A, and 25A are diagrams corresponding to a cross section taken along line A1-A1′ of FIG. 1. FIGS. 16B, 17C, 18C, 19B, 20B, and 21B are diagrams corresponding to a cross section taken along line A2-A2′ of FIG. 1. FIGS. 15C, 17D, and 18D are diagrams corresponding to a cross section taken along line B1-B1′ of FIG. 1. FIGS. 17E and 18E are diagrams corresponding to a cross section taken along line B2-B2′ of FIG. 1, and FIGS. 13B, 14B, 16C, 19C, 20C, 21C, 22B, 24B, and 25B. Hereinafter, FIGS. 11 through 25B will be described.

Referring to FIG. 11, an inter-layer insulation layer IL (see FIG. 13B), the first base insulation layer 142, and a lower channel stack ST1 may be formed above a substrate 110 including a first surface 110F and a second surface 110B. The lower channel stack ST1 may include the plurality of lower nanosheets NS1 and a plurality of lower sacrificial layers NG1 which are alternately disposed.

According to an example embodiment, the plurality of lower nanosheets NS1 may include a group IV semiconductor such as silicon (Si) or germanium (Ge), a group IV-IV compound semiconductor such as silicon-germanium (SiGe) or silicon carbide (SiC), or a group III-V compound semiconductor such as gallium arsenide (GaAs), indium arsenide (InAs), or indium phosphide (InP). The plurality of lower sacrificial layers NG1 may include a material having an etch selectivity for the plurality of lower nanosheets NS1. In some example embodiments, the plurality of lower nanosheets NS1 may include silicon (Si), and the plurality of lower sacrificial layer NG1 may include silicon-germanium (SiGe). In some example embodiments, the plurality of lower nanosheets NS1 and the plurality of lower sacrificial layers NG1 may be formed by an epitaxial growth process. The epitaxial growth process may be a chemical vapor deposition (CVD) process such as vapor-phase epitaxy (VPE) or ultra-high vacuum chemical vapor deposition (UHV-CVD), molecular beam epitaxy, or a combination thereof.

According to an example embodiment, an upper channel stack ST2 may be formed above the lower channel stack ST1. The upper channel stack ST2 may include the plurality of upper nanosheets NS2 and a plurality of upper sacrificial layers NG2 which are alternately disposed. At this point, according to an example embodiment, a thickness of a lowermost upper sacrificial layer NG2 among the plurality of upper sacrificial layers NG2 may be larger than a thickness of another upper sacrificial layer NG2. However, it is merely an example. In some example embodiments, respective thicknesses of the plurality of upper sacrificial layers NG2 may be equal.

According to an example embodiment, the plurality of upper nanosheets NS2 may include a group IV semiconductor such as silicon (Si) or germanium (Ge), a group IV-IV compound semiconductor such as silicon-germanium (SiGe) or silicon carbide (SiC), or a group III-V compound semiconductor such as gallium arsenide (GaAs), indium arsenide (InAs), or indium phosphide (InP). The plurality of upper sacrificial layers NG2 may include a material having an etch selectivity for the plurality of upper nanosheets NS2.

Afterward, a plurality of dummy gate lines 410 extended in the third direction D3 may be formed. The plurality of dummy gate lines 410 may be disposed to be spaced apart from each other at an equal interval in the second direction D2. In example embodiments, the plurality of dummy gate lines 410 may be formed by using at least one of silicon oxide, silicon nitride, polysilicon, or a spin-on hardmask. Each of the plurality of dummy gate lines 410 may have a double layer structure including different materials. The spacer 126 may be formed on side walls of the plurality of dummy gate lines 410.

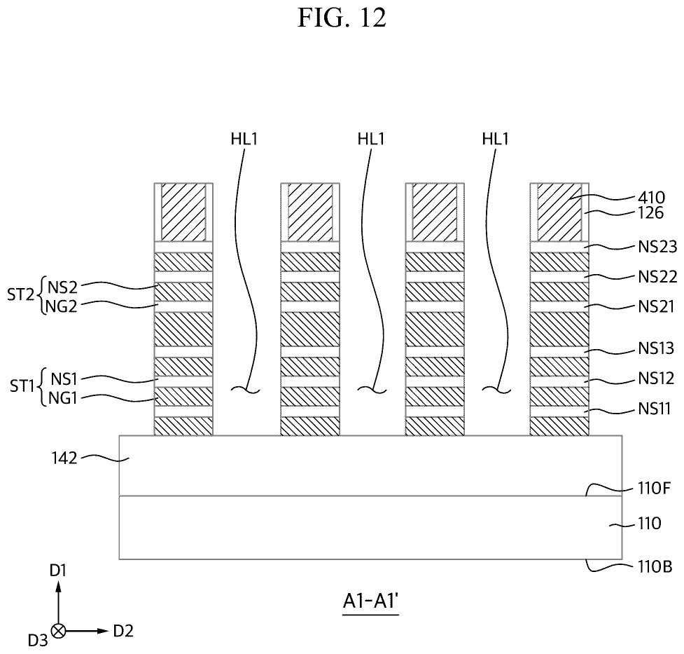

Referring to FIG. 12, the upper channel stack ST2 and the lower channel stack ST1 may be etched by using the plurality of dummy gate lines 410 and the spacer 126 as an etch mask, so that a first opening portion HL1 extended in the third direction D3 may be formed.

Referring to FIGS. 13A and 13B, a semiconductor material may be epitaxially grown in the first opening portion HL1, so that the first source/drain area SD1 may be formed. The first source/drain area SD1 may cover a side wall of each of the plurality of lower nanosheets NS1, which crosses the second direction D2. An upper surface of the first source/drain area SD1 may be positioned at a level lower in the first direction D1 than a lower surface of the lowermost first upper nanosheet NS21.

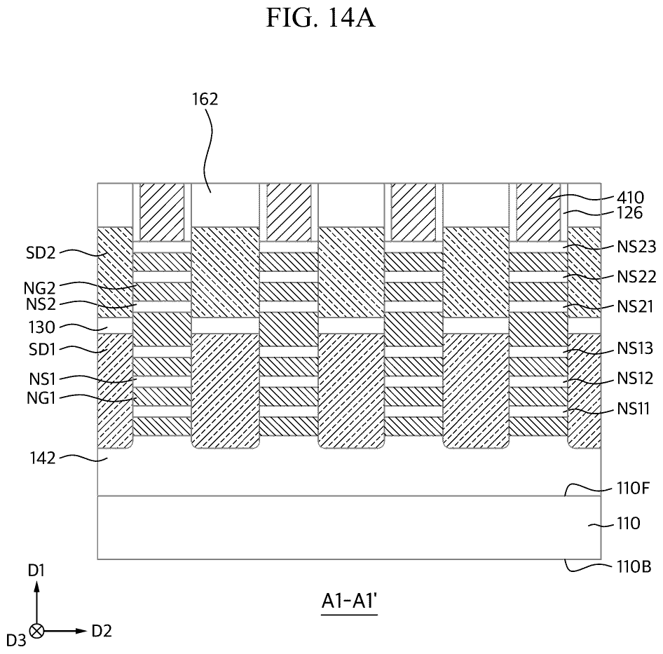

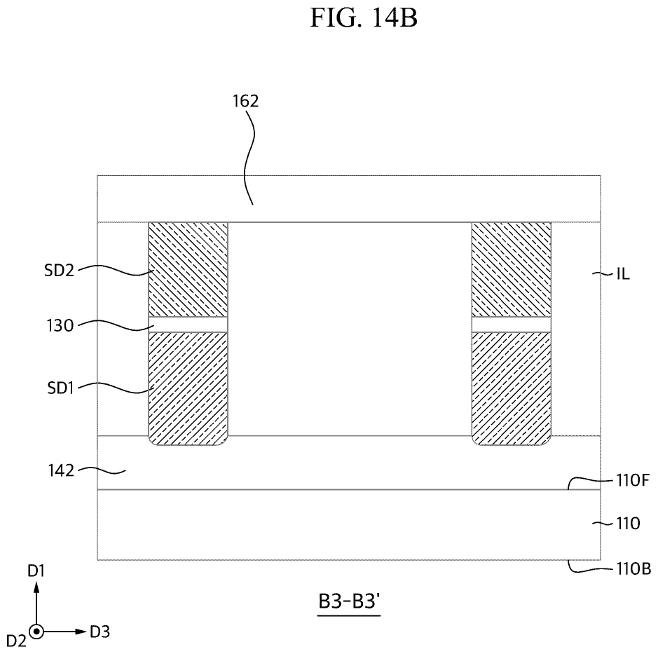

Referring to FIGS. 14A and 14B, the separation part 130, the second source/drain area SD2, and the first insulation layer 162 may be formed in the first opening portion HL1. The separation part 130 may be formed to cover the upper surface of the first source/drain area SD1 in the opening portion HL1. The separation part 130 may be in contact with a side wall of the lowermost upper sacrificial layer NG2 among the plurality of upper sacrificial layer NG2. An upper surface of the separation part 130 may be positioned at a level lower in the first direction D1 than the lower surface of the first upper nanosheet NS21. The separation part 130 may be configured to electrically insulate the first source/drain area SD1 and the second source/drain area SD2 which is to be formed later from each other.

Then, a semiconductor material may be epitaxially grown in the first opening portion HL1 (see FIG. 13A), so that the source/drain area SD2 may be formed. The second source/drain area SD2 may cover a side wall of each of the plurality of lower nanosheets NS2, which crosses the second direction D2. An upper surface of the second source/drain area SD2 may be positioned at a level higher in the first direction D1 than an upper surface of the uppermost third upper nanosheet NS23.

Then, the first insulation layer 162 which covers the upper surface of the second source/drain area SD2 may be formed. The insulation layer 162 may cover an outer side wall of the spacer 126. In some example embodiments, a planarization process may be formed after the first insulation layer 162 is formed. The planarization process may include, for example, a chemical mechanical polishing (CMP) process, but it is merely an example.

Referring to FIGS. 15A, 15B, and 15C, a dummy gate line 410 illustrated in FIG. 14A may be removed, and the upper channel stack ST2 may be exposed. Then, the plurality of lower sacrificial layers NG1 (hereinafter, see FIG. 14A) and the plurality of upper sacrificial layers NG2 (hereinafter, see FIG. 14A) may be removed, so that a surface of each of the plurality of lower nanosheets NS1 and the plurality of upper nanosheets NS2 may be exposed. A process of removing the plurality of lower sacrificial layers NG1 and the plurality of upper sacrificial layers NG2 may be a wet etching process using an etch selectivity.

Afterward, the lower gate insulation layer 122 and the first gate line GL1 may be formed in a space in which the plurality of lower sacrificial layers NG1 is removed, and the upper gate insulation layer 124 and the second gate line GL2 may be formed in a spaced in which the plurality of upper sacrificial layers NG2 is removed. At this point, the first gate line GL1 and the second gate line GL2 each may be spaced apart in the second direction D2 and extended in the third direction D3.

In example embodiments, the first gate line GL1 and the second gate line GL2 may include a work function conductive layer and an embedded conductive layer. In example embodiments, the work function conductive layer may include aluminum (Al), copper (Cu), titanium (Ti), tantalum (Ta), tungsten (W), molybdenum (Mo), tantalum nitride (TaN), nickel silicide (NiSi), cobalt silicide (CoSi), titanium nitride (TiN), tungsten nitride (WN), titanium aluminide (TiAl), titanium aluminum carbide (TiAlC), titanium aluminum nitride (TiAlN), tantalum carbonitride (TaCN), tantlum carbide (TaC), tantalum silicon nitride (TaSiN), or a combination thereof. The embedded conductive layer may include aluminum (Al), copper (Cu), titanium (Ti), tantalum (Ta), tungsten (W), molybdenum (Mo), tantalum nitride (TaN), nickel silicide (NiSi), cobalt silicide (CoSi), titanium nitride (TiN), tungsten nitride (WN), titanium aluminide (TiAl), titanium aluminum carbide (TiAlC), titanium aluminum nitride (TiAlN), tantalum carbonitride (TaCN), tantalum carbide (TaC), tantalum silicon nitride (TaSiN), or a combination thereof.

Then, the gate capping layer 128 may be formed on the second gate line GL2.

Referring to FIGS. 16A, 16B, and 16C, the gate separation structure 150, which crosses the plurality of second gate lines GL2 and the plurality of first gate lines GL1 which are extended in the third direction D3, may be formed. The gate separation structure 150 may be extended in the second direction D2 to cut the plurality of second gate lines GL2 and the plurality of first gate lines GL1.

According to an example embodiment, the gate separation structure 150 may be formed by penetrating the plurality of first gate lines GL1, the plurality of second gate lines GL2, an inter-layer insulation film IL, and the first base insulation layer 142. A portion of the plurality of first gate lines GL1, the plurality of second gate lines GL2, the inter-layer insulation film IL, and the first base insulation layer 142 may be etched in the first direction D1 and the third direction D3. Then, the gate separation liner 152 may be formed to be conformal in an etched space. An atomic layer deposition (ALD) method may be used to form the gate separation liner 152, but it is merely an example. After the gate separation liner 152 is formed, the gate separation oxide film 154 may be formed on the gate separation liner 152. According to an example embodiment, the gate separation oxide film 154 may have a tapered shape of which a width is narrowed in a direction to the substrate 110.

Referring to FIGS. 17A, 17B, 17C, 17D, and 17E, the gate separation structure 150 may be etched, so that a plurality of second opening portions HL2 and a plurality of third opening portions HL3 extended in the first direction D1 and the third direction D3 may be formed.

In an example embodiment, the plurality of second opening portions HL2 and the plurality of third opening portions HL3 each may be arranged to be spaced apart in the second direction D2. When viewed from above in the first direction D1, only the gate separation structure 150 may be etched without etching the second gate line GL2, so that a second opening portion HL2 may be formed. A boundary of the second opening portion HL2, which is parallel to the second direction D2, and an outer side wall of the gate separation liner 152 may be positioned on an identical plane. The plurality of second opening portions HL2 may have a tapered shape of which a width is narrowed in a direction to the substrate 110. A length of each of the plurality of second opening portions HL2 in the third direction D3 may be equal to a length of the gate separation structure 150 in the third direction D3.

According to an example embodiment, when viewed from above in the first direction D1, the gate separation structure 150, the inter-layer insulation film IL, the second gate line GL2, and the first gate line GL1 may be etched, so that a third opening portion HL3 may be formed. A boundary of the third opening portion HL3, which is parallel to the second direction D2, and an outer side wall of the gate separation liner 152 may be positioned on an identical plane. The plurality of third opening portions HL3 may have a tapered shape of which a width is narrowed in a direction to the substrate 110. A length of each of the plurality of third opening portions HL3 in the third direction D3 may longer than the length of the gate separation structure 150 in the third direction D3 and a length of the second opening portion HL2 in the third direction D3.

According to an example embodiment, a depth of the second opening portion HL2 in the first direction D1 and a depth of the third opening portion HL3 in the third direction D1 may be equal to each other. In addition, levels of a lower surface of the second opening portion HL2 and a lower surface of the third opening portion HL3 in the first direction D1 may be positioned to be further lower than a level of a lower surface of the first gate line GL1 in the first direction D1.

Referring to FIGS. 18A, 18B, 18C, 18D, and 18E, the plurality of second opening portions HL2 may be filled with an insulation material, so that the first diffusion breaker 210 may be formed, and the plurality of third opening portions HL3 may be filled with an insulation material, so that the second diffusion breaker 220 may be formed. A shape of the first diffusion breaker 210 may correspond to the second opening portion HL2, and a shape of the second diffusion breaker 220 may correspond to the third opening portion HL3. Thus, a description of structural properties of the second opening portion HL2 and the third opening portion HL3 with reference to FIGS. 17A through 17E may be applied to a description of structural properties of the first diffusion breaker 210 and the second diffusion breaker 220.

According to an example embodiment, the first diffusion breaker 210 and the second diffusion breaker 220 each may be in contact with a side wall of the first gate line GL1 and a side wall of the gate line GL2 in the third direction. The expression “A may be in contact with B in a direction” means that A and B, which form a contact interface therebetween, may be arranged along the stated direction, and the contact interface may intersect either the stated direction or a direction inclined with respect thereto. Also, the first diffusion breaker 210 and the second diffusion breaker 220 each may be in contact with the gate separation oxide film 154.

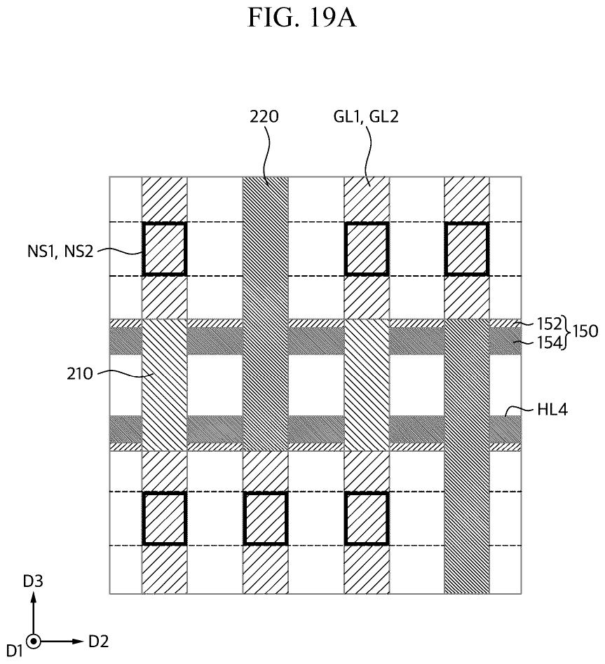

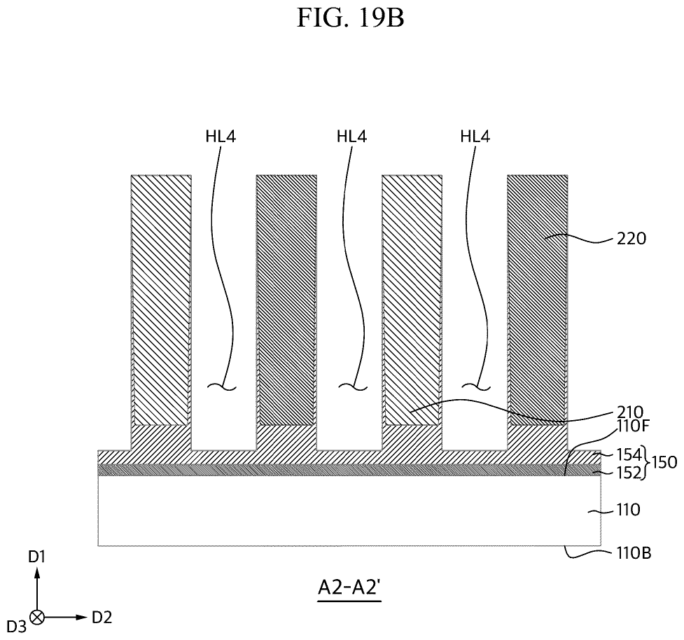

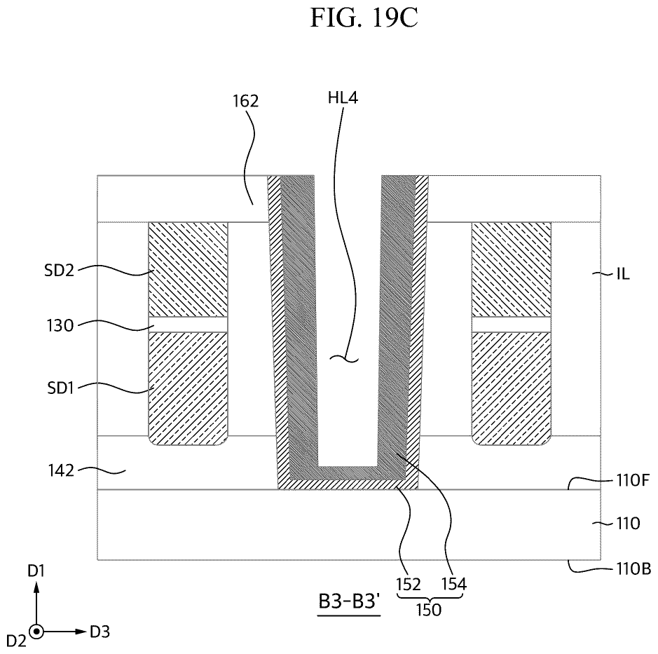

Referring to FIGS. 19A, 19B, and 19C, a plurality of fourth opening portions HL4 arranged in a direction intersecting a plurality of first diffusion breakers 210 and a plurality of second diffusion breakers 220. The gate separation oxide film 154 may be etched in the first direction D1, so that the plurality of fourth opening portions HL4 may be formed.

According to an example embodiment, a process of etching the gate separation oxide film 154 may be a process using an etch selectivity. The first diffusion breaker 210 and the second diffusion breaker 220 may include a material having the etch selectivity for the gate separation oxide film 154. Thus, although the gate separation oxide film 154 is etched in the first direction D1 in order to form a fourth opening portion HL4, etching the first diffusion breaker 210 and the second diffusion breaker 220 may be performed greatly slowly compared to etching the gate separation oxide film 154. Thus, although the fourth opening portion HL4 is formed as an etching process for the gate separation oxide film 154 is completed, the first diffusion breaker 210 and the second diffusion breaker 220 may be approximately not etched.

According to an example embodiment, the plurality of fourth opening portions HL4 may be formed to be spaced apart in the second direction D2. When viewed from above in the first direction D1, a boundary of the fourth opening portion HL4, which is parallel to the third direction D3, may correspond to an outline of the first diffusion breaker 210 or an outline of the second diffusion breaker 220. Boundaries of the plurality of fourth opening portions HL4, which are parallel to the second direction D2, may be positioned on an identical line.

According to an example embodiment, levels of lower surfaces of the plurality of fourth opening portions HL4 in the first direction D1 may be positioned to be lower than a level of a lower surface of the first diffusion breaker 210 in the first direction D1 and a level of a lower surface of the second diffusion breaker 220 in the first direction D1. In addition, in some example embodiments, the levels of the lower surfaces of the plurality of fourth opening portions HL4 in the first direction D1 may be positioned to be lower than a level of an upper surface of the first base insulation layer 142 in the first direction D1. However, it is merely an example.

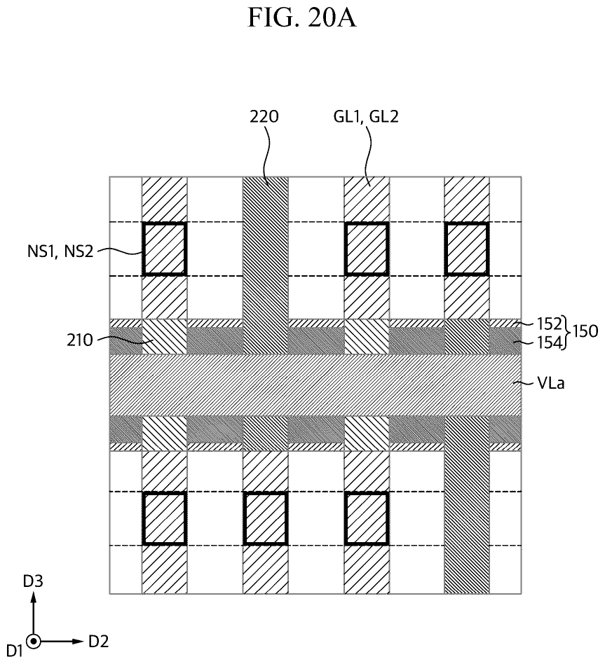

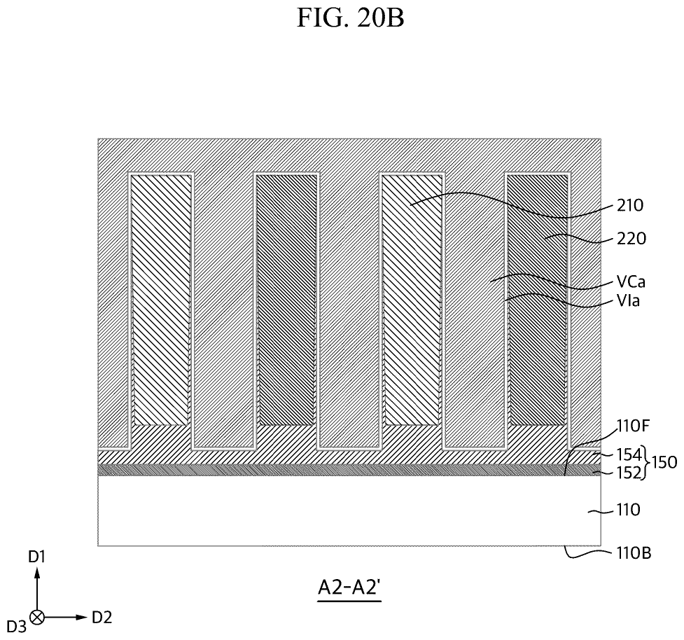

Referring to FIGS. 20A and 20B, a conductive material VCa and an insulation material VIa may be formed in the plurality of fourth opening portions HL4. To begin with, the insulation material VIa which covers spaces in the plurality of fourth opening portions HL4 in a conformal manner may be formed. A constant thickness of the insulation material VIa may cover the spaces in the plurality of fourth opening portion HL4, an upper surface of the first diffusion breaker 210, and an upper surface of the second diffusion breaker 220. The atomic layer deposition method may be used in a process of forming the insulation material VIa, but a method of forming the insulation material VIa is not limited thereto.

According to an example embodiment, after the insulation material VIa is formed, the conductive material VCa may be deposited on the insulation material VIa. The conductive material VCa may completely fill the spaces in the plurality of fourth opening portions HL4. In addition, an upper surface of the conductive material VCa may be formed to be higher than the upper surface of the first diffusion breaker 210 and the upper surface of the second diffusion breaker 220. The upper surface of the conductive material VCa may be formed to be higher than an upper surface of the insulation material VIa on the first diffusion breaker 210 and the second diffusion breaker 220.

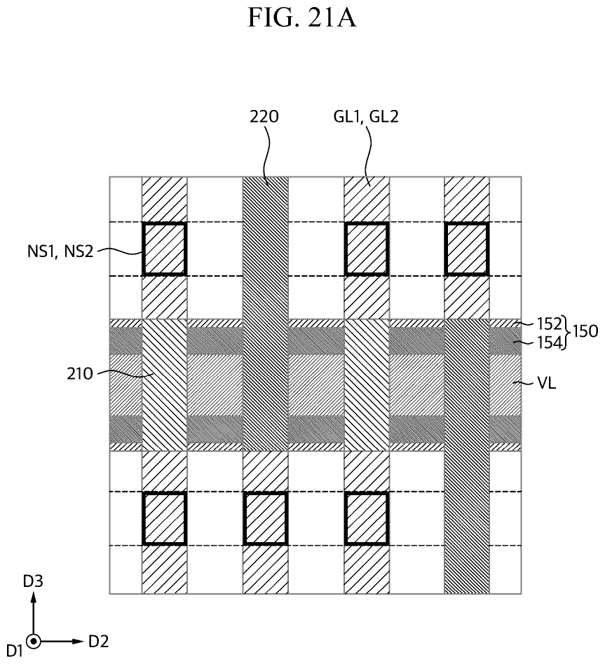

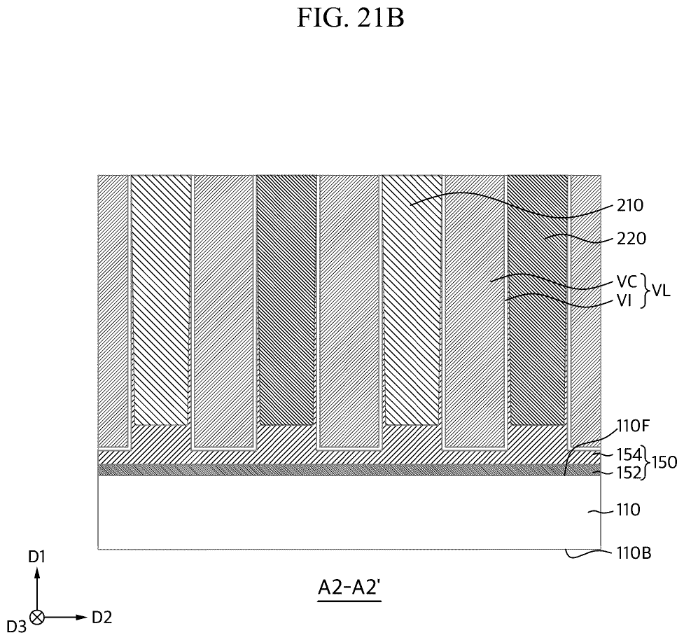

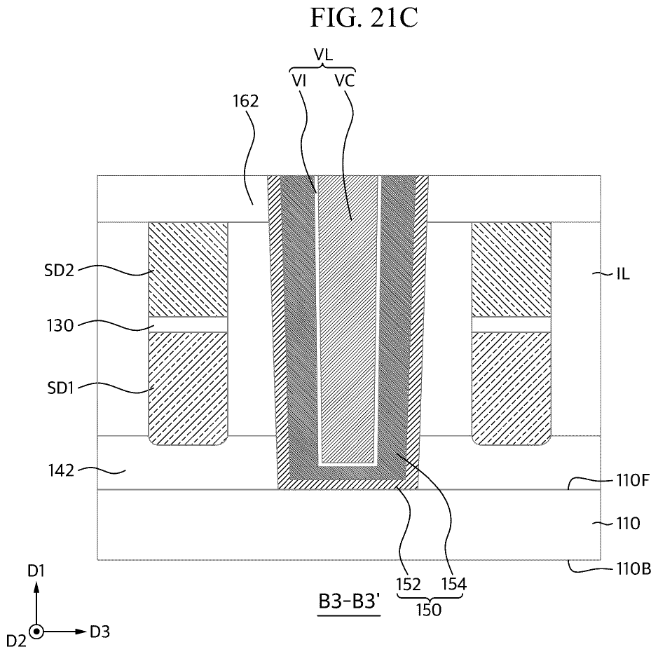

Referring to FIGS. 21A and 21B, an upper end portion of the conductive material VCa (see FIG. 20B) may be removed, so that the conductor VC may be formed. An upper end portion of the insulation material VIa (see FIG. 20B) may be removed, so that the insulation liner VI may be formed. The conductor VC and the insulation liner VI may be formed, and through this, the conductive rail VL which is formed with the conductor VC and the insulation liner VI may be completed.

According to an example embodiment, the upper end portion of the conductive material VCa and the upper end portion of the insulation material VIa may be removed through a planarization process. After the planarization process, the upper surface of the first diffusion breaker 210, the upper surface of the second diffusion breaker 220, an upper surface of the conductor VC, and an uppermost surface of the insulation liner VI all may be positioned on an identical plane. After the planarization process, the upper surface of the first diffusion breaker 210 and the upper surface of the second diffusion breaker 220 all may be exposed when viewed in the first direction D1. Also, the plurality of conductive rails VL may be provided, and the plurality of conductive rails VL may be arranged to be spaced apart in the second direction D2. The first diffusion breaker 210 or the second diffusion breaker 220 may be positioned between the plurality of conductive rails VL. The planarization process may include, for example, a chemical mechanical polishing process, but it is merely an example.

According to an example embodiment, since the first diffusion breaker 210 and the second diffusion breaker 220 include the material having the etch selectivity for the gate separation oxide film 154, the conductive rail VL may be elaborately completed only with an etching process, a deposition process, and a planarization process without a photomask in a series of processes of FIGS. 19A through 21B.

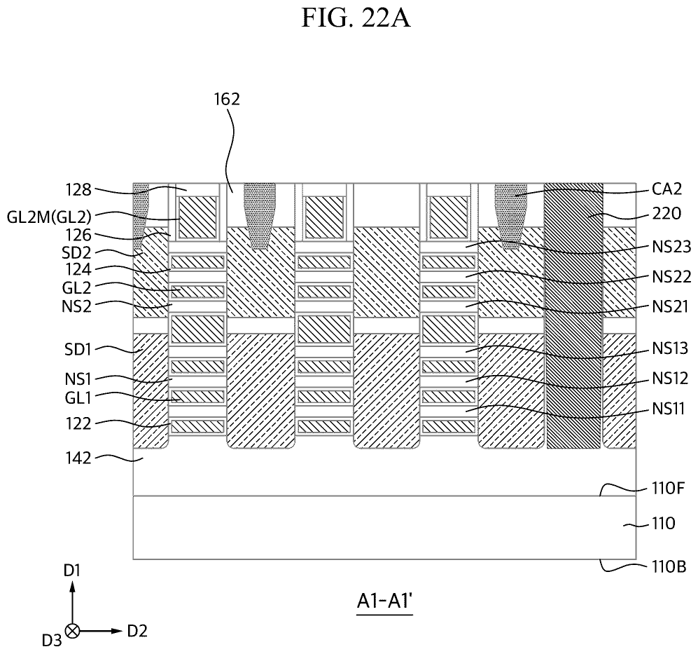

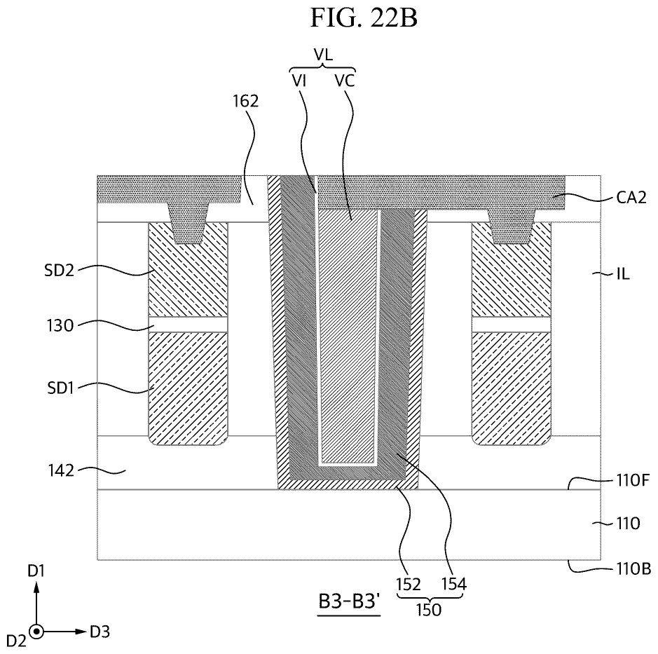

Referring to FIGS. 22A and 22B, a mask pattern (not illustrated) may be formed on the first insulation layer 162, and a portion of the first insulation layer 162 may be removed by using the mask pattern, so that a second contact hole (not illustrated) may be formed. The second contact hole may be formed to have a depth at which an upper end portion of the second source/drain area SD2 is exposed. In addition, a portion of an upper end portion of the gate separation structure 150 and a portion of an upper end portion of the conductive rail VL may be removed in order to form the second contact hole. Afterward, the second contact hole may be filled with a conductive material, so that the second contact CA2 may be formed.

According to an example embodiment, the second contact CA2 may include an extended portion extended in the third direction D3 and a via portion extended in the first direction D1 from the extended portion. The extended portion may be in contact with the upper surface of the conductor VC of the conductive rail VL to be electrically connected to the conductive rail VL. The via portion may be in contact with the upper end portion of the second source/drain area SD2 to be electrically connected to the second source/drain area SD2. In other words, the second contact CA2 may electrically connect the conductive rail VL and the second source/drain area SD2.

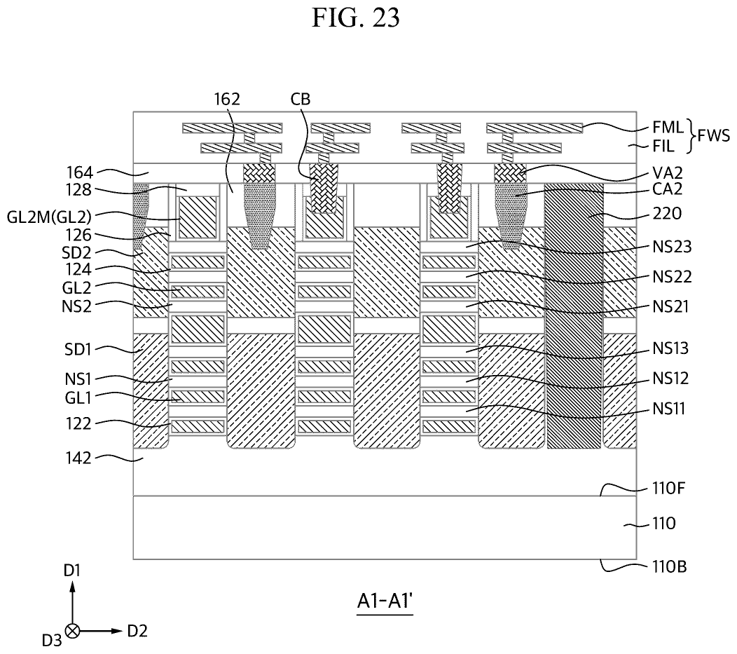

Referring to FIG. 23, the second insulation layer 164 may be formed on the second contact CA2 and the first insulation layer 162, and a portion of the second insulation layer 164 may be removed, so that a second via hole (not illustrated) and a gate contact hole (not illustrated) may be formed. Afterward, the second via hole and the gate contact hole may be filled with a conductive material, so that the second via VA2 and the gate contact CB may be formed. Then, the front-side wiring structure FWS which is electrically connected to the second via VA2 and the gate contact CB may be formed.

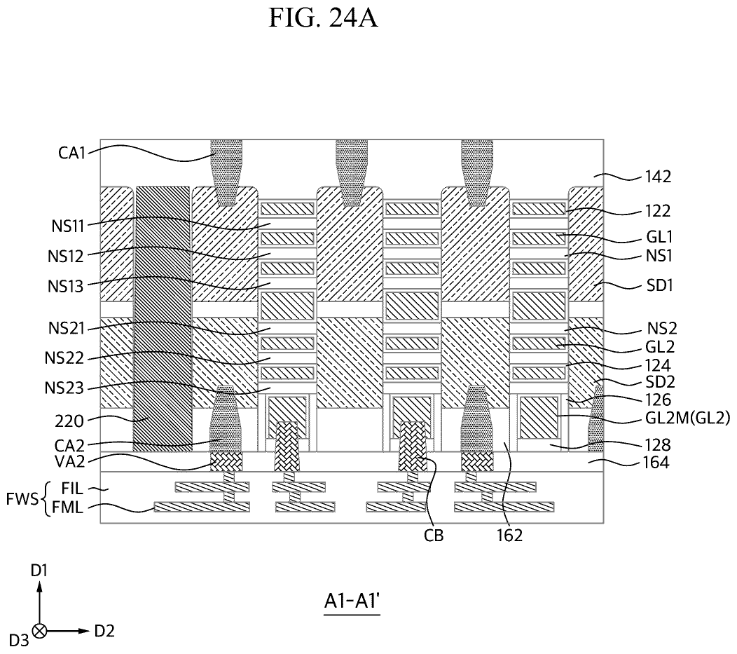

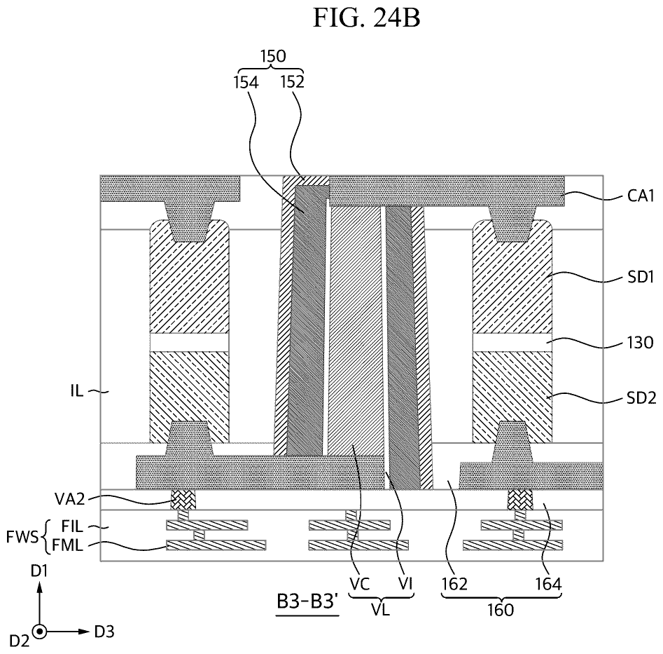

Referring to FIGS. 24A and 24B, the substrate 110 may be flipped so that the second surface 110B (see FIG. 23) of the substrate 110 (see FIG. 23) faces upward, and the substrate 110 may be ground to be thin until the first base insulation layer 142 is exposed from the second surface 110B of the substrate 110.

Afterward, a wet etching process may be performed on the substrate 110, so that a remaining portion of the substrate 110 may be removed. The first base insulation layer 142 may remain and not be removed during the wet etching process. An upper surface of the first base insulation layer 142 may be exposed after the substrate 110 is removed.

Then, a mask pattern (not illustrated) may be formed on the first insulation layer 142, and a portion of the first insulation layer 142 may be removed by using the mask pattern, so that a first contact hole (not illustrated) may be formed. The first contact hole may be formed to have a depth at which the first source/drain area SD1 is exposed. Also, a portion of a lower end portion (which is a narrow area in a tapered structure) of the gate separation structure 150 and a portion of a lower end portion (which is a narrow area in a tapered structure) of the conductive rail VL may be removed in order to form the first contact hole. Afterward, the first contact hole may be filled with a conductive material, so that the first contact CA1 may be formed.

According to an example embodiment, the first contact CA1 may include an extended portion extended in the third direction D3 and a via portion extended in the first direction D1 from the extended portion. The extended portion may be in contact with a lower surface (which is a surface having a most narrow vertical cross section in a tapered structure) of the conductor VC of the conductive rail VL to be electrically connected to the conductive rail VL. The via portion may be in contact with the first source/drain area SD1 to be electrically connected to the first source/drain area SD1. In other words, the first contact CA1 may electrically connect the conductive rail VL and the first source/drain area SD1.

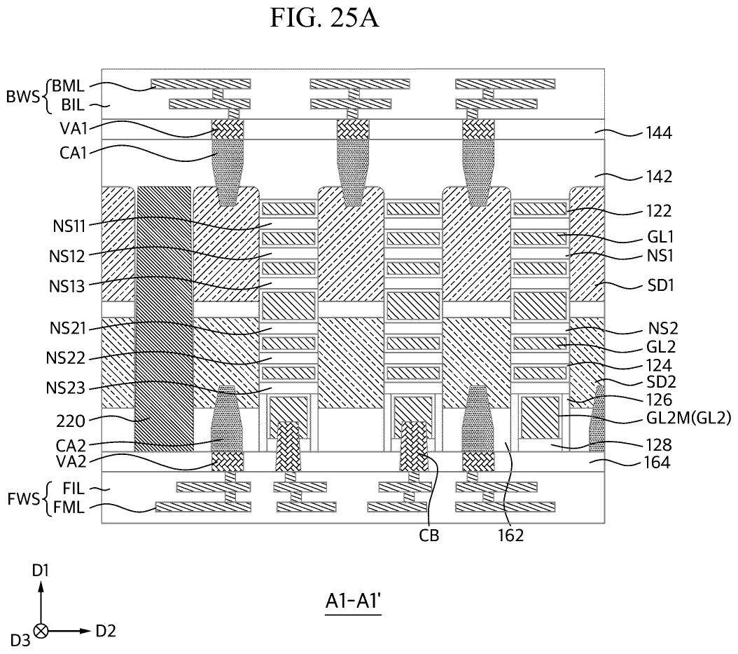

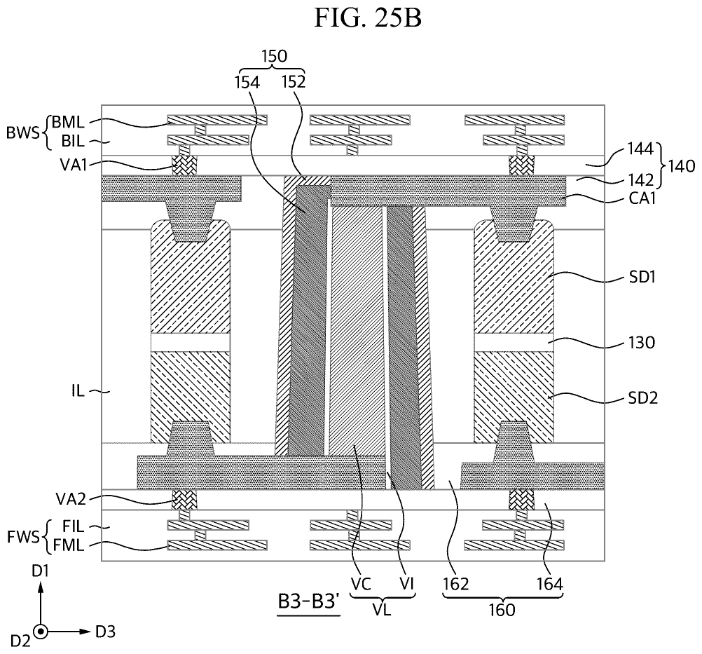

Referring to FIGS. 25A and 25B, the second base insulation layer 144 may be formed on the first contact CA1 and the first base insulation layer 142, and a portion of the second base insulation layer 144 may be removed, so that a first via hole (not illustrated) may be formed. Afterward, the first via hole may be filled with a conductive material, so that the first via VA1 may be formed. Then, the backside wiring structure BWS which is electrically connected to the first via VA1 may be formed.

As described above, the example embodiments have been disclosed in the drawings and the present disclosure. The example embodiments have been described with a specific term in the present disclosure, but the term is used merely to describe the technical spirit of the present disclosure, not to limit a meaning or the scope of the present disclosure described in the accompanying claims. Therefore, those skilled in the art will understand that various modifications or other equivalent example embodiments are possible therefrom

What is claimed is:

1. An integrated circuit device comprising:
a plurality of first source/drain areas;
a plurality of second source/drain areas spaced apart from the plurality of first source/drain areas in a first direction and stacked above the plurality of first source/drain areas in the first direction;
a first contact disposed on a lower surface of each of the plurality of first source/drain areas in the first direction;
a second contact disposed on an upper surface of each of the plurality of second source/drain areas in the first direction;
a conductive rail electrically connected to the first contact or the second contact and extending in the first direction;
a first diffusion breaker disposed beside the conductive rail in a second direction intersecting the first direction; and
a second diffusion breaker spaced apart from the first diffusion breaker in the second direction with the conductive rail in between,
wherein the conductive rail overlaps the first diffusion breaker and the second diffusion breaker in the second direction.

2. The integrated circuit device of claim 1, wherein a length of the second diffusion breaker in a third direction intersecting the first direction and the second direction is longer than a length of the first diffusion breaker in the third direction.

3. The integrated circuit device of claim 1, wherein a level of a lower surface of the conductive rail in the first direction is lower than a level of a lower surface of the first diffusion breaker in the first direction and a level of a lower surface of the second diffusion breaker in the first direction.

4. The integrated circuit device of claim 1, wherein a level of a lower surface of the conductive rail in the first direction is substantially equal to a level of a lower surface of the first diffusion breaker in the first direction and a level of a lower surface of the second diffusion breaker in the first direction.

5. The integrated circuit device of claim 1, wherein a level of a lower surface of the conductive rail in the first direction is higher than a level of a lower surface of the first diffusion breaker in the first direction and a level of a lower surface of the second diffusion breaker in the first direction.

6. The integrated circuit device of claim 1, wherein an upper surface of the first diffusion breaker, an upper surface of the second diffusion breaker, and an uppermost surface of the conductive rail are coplanar with each other.

7. The integrated circuit device of claim 1, further comprising a first gate line positioned between a pair of first source/drain areas adjacent to each other in the second direction among the plurality of first source/drain areas,
wherein the first diffusion breaker is in contact with a side surface of the first gate line.

8. The integrated circuit device of claim 1, further comprising a second gate line positioned between a pair of second source/drain areas adjacent to each other in the second direction among the plurality of second source/drain areas,
wherein the first diffusion breaker is in contact with a side surface of the second gate line, in a third direction intersecting the first direction and the second direction.

9. The integrated circuit device of claim 1, wherein the first diffusion breaker and the second diffusion breaker include an insulation material.

10. An integrated circuit device comprising:
a plurality of first transistors including a plurality of first source/drain areas, a plurality of lower nanosheets connected to the plurality of first source/drain areas and spaced apart from each other in a first direction, a first gate line surrounding the plurality of lower nanosheets, and a first contact disposed on a lower surface of each of the plurality of first source/drain areas in the first direction;
a plurality of second transistors including a plurality of second source/drain areas, a plurality of upper nanosheets connected to the plurality of second source/drain areas and spaced apart from each other in the first direction, a second gate line surrounding the plurality of upper nanosheets, and a second contact disposed on an upper surface of each of the plurality of second source/drain areas in the first direction;
a plurality of conductive rails each extending in the first direction to connect one of the plurality of first transistors and one of the plurality of second transistors;
a first diffusion breaker disposed beside one of the plurality of conductive rails in a second direction intersecting the first direction;
a second diffusion breaker spaced apart from the first diffusion breaker in the second direction with the one of the plurality of conductive rails in between; and
a gate separation structure positioned between a pair of second transistors adjacent in a third direction intersecting the first direction and the second direction among the plurality of second transistors,
wherein the conductive rails overlap the first diffusion breaker and the second diffusion breaker in the second direction.

11. The integrated circuit device of claim 10, wherein the first diffusion breaker and the second diffusion breaker have an etch selectivity for the gate separation structure.

12. The integrated circuit device of claim 10, wherein the first diffusion breaker or the second diffusion breaker is positioned between a pair of conductive rails adjacent to each other in the second direction among the plurality of conductive rails.

13. The integrated circuit device of claim 10, wherein at least a portion of the first diffusion breaker and at least a portion of the second diffusion breaker are embedded in the gate separation structure.

14. The integrated circuit device of claim 10, wherein the plurality of conductive rails is embedded in the gate separation structure.

15. The integrated circuit device of claim 14, further comprising:
a gate separation oxide film surrounding the plurality of conductive rails; and
a gate separation liner surrounding the gate separation oxide film.

16. The integrated circuit device of claim 10, wherein a length of the first diffusion breaker in the third direction is greater than a length of the gate separation structure in the third direction.

17. The integrated circuit device of claim 10, wherein a length of the first diffusion breaker in the third direction is less than a length of the gate separation structure in the third direction.

18. The integrated circuit device of claim 10, wherein the first diffusion breaker is positioned between the pair of second transistors adjacent in the third direction intersecting the first direction and the second direction among the plurality of second transistors.

19. An integrated circuit device comprising:
a plurality of first source/drain areas;
a first contact disposed on a lower surface of each of the plurality of first source/drain areas in a first direction;
a plurality of lower nanosheets connected to the plurality of first source/drain areas and spaced apart from each other in the first direction;
a first gate line surrounding the plurality of lower nanosheets and extending in a second direction intersecting the first direction;
a plurality of second source/drain areas spaced apart from the plurality of first source/drain areas in the first direction and stacked above the plurality of first source/drain areas in the first direction;
a second contact disposed on a lower surface of each of the plurality of second source/drain areas in the first direction;
a plurality of upper nanosheets connected to the plurality of second source/drain areas and spaced apart from each other in the first direction;
a second gate line surrounding the plurality of upper nanosheets and extending in the second direction;
a conductive rail electrically connected to the first contact and the second contact and extending in the first direction;
a first diffusion breaker that is disposed beside the conductive rail in a third direction intersecting the first direction and the second direction and is in contact with a side surface of the first gate line and a side surface of the second gate line in the second direction; and
a second diffusion breaker spaced apart from the first diffusion breaker in the third direction with the conductive rail in between,
wherein the conductive rail overlaps the first diffusion breaker and the second diffusion breaker in the third direction.

20. The integrated circuit device of claim 19, wherein the second diffusion breaker is positioned:
between a pair of first source/drain areas adjacent to each other in the third direction among the plurality of first source/drain areas; and
between a pair of second source/drain areas adjacent to each other in the third direction among the plurality of second source/drain areas.
